(19) United States
(12) Patent Application Publication
(10) Pub. No.: US 2026/0090396 A1
(43) Pub. Date: Mar. 26, 2026

(54) SEMICONDUCTOR DEVICE

(71) Applicant: Samsung Electronics Co., Ltd., Suwon-si (KR)

(72) Inventors: Hyeon Seok YEOM, Suwon-si (KR); Sang Hyeon KIM, Suwon-si (KR); Il Hwan KIM, Suwon-si (KR); Jeong Hyun KIM, Suwon-si (KR); Jong Hwa BAEK, Suwon-si (KR); Ha Chul SHIN, Suwon-si (KR)

(21) Appl. No.: 19/214,576

(22) Filed: May 21, 2025

(30) Foreign Application Priority Data
Sep. 20, 2024 (KR) 10-2024-0127202

(51) Int. Cl. H01L 23/544; H10D 84/90; H10D 89/10

(52) U.S. Cl. CPC H10W 46/00; H10D 84/953; H10D 89/10; H10W 46/301

(57) ABSTRACT

There is provided a semiconductor device capable of improving element performance and the degree of integration of elements by forming an alignment mark that may prevent misalignment in a photo process. The semiconductor device includes a base film, a plurality of lower alignment insulating patterns disposed on the base film, and an upper alignment insulating pattern disposed on the lower alignment insulating patterns, extending in a first direction, and in direct contact with each of the lower alignment insulating patterns, wherein the lower alignment insulating patterns extend in a second direction perpendicular to the first direction and are spaced apart from each other in the first direction.

### CROSS-REFERENCE TO RELATED APPLICATION

This application claims priority under 35 U.S.C. § 119 from Korean Patent Application No. 10-2024-0127202, filed on Sep. 20, 2024, in the Korean Intellectual Property Office, and all the benefits accruing therefrom under 35 U.S.C. § 119, the contents of which in its entirety are herein incorporated by reference.

### BACKGROUND

### 1. Technical Field

The present disclosure relates to a semiconductor device.

### 2. Description of the Related Art

Recently, with the rapid spread of information media, the functions of semiconductor devices are also developing rapidly. In recent semiconductor products, high integration of products is required to ensure competitiveness, low cost, and high quality. To achieve high integration, the semiconductor devices are being scaled down.

As the degree of integration of the semiconductor devices increases, design rules for components of the semiconductor devices are decreasing. In manufacturing the semiconductor devices with fine patterns corresponding to the trend toward high integration of the semiconductor devices, the importance of photolithography process is emerging.

In manufacturing the semiconductor devices, numerous photolithography processes are performed. To perform an accurate photolithography process, alignment between the structure already formed on a semiconductor substrate and a photomask is important. To align the photomask and the semiconductor substrate, an alignment mark is formed on the semiconductor substrate.

### SUMMARY

Aspects of the present disclosure provide a semiconductor device capable of improving element performance and the degree of integration of elements by forming an alignment mark that may prevent misalignment in a photo process.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising, a base film, a plurality of lower alignment insulating patterns disposed on the base film, and an upper alignment insulating pattern disposed on the lower alignment insulating patterns, extending in a first direction, and in direct contact with each of the lower alignment insulating patterns, wherein the lower alignment insulating patterns extend in a second direction perpendicular to the first direction and are spaced apart from each other in the first direction.

According to another aspect of the present disclosure, there is provided a semiconductor device comprising, a first lower pattern including a plurality of first sub-fin type patterns extending in a first direction, a second lower pattern including a plurality of second sub-fin type patterns extending in a second direction perpendicular to the first direction, a first alignment mark pattern including a plurality of first lower alignment insulating patterns disposed between the first sub-fin type patterns adjacent to each other in the second direction, and a first upper alignment insulating pattern disposed on the first lower alignment insulating patterns, and a second alignment mark pattern including a plurality of second lower alignment insulating patterns disposed between the second sub-fin type patterns adjacent to each other in the first direction, and a second upper alignment insulating pattern disposed on the second lower alignment insulating patterns, wherein the first upper alignment insulating pattern extends in the second direction and is in direct contact with each of the first lower alignment insulating patterns, and wherein the second upper alignment insulating pattern extends in the first direction and is in direct contact with each of the second lower alignment insulating patterns.

According to another aspect of the present disclosure, there is provided a semiconductor device comprising, an active pattern disposed in a logic cell area, extending in a first direction, and including a first sidewall and a second sidewall opposite to each other in a second direction perpendicular to the first direction, a channel separation structure extending in the first direction and in contact with the first sidewall of the active pattern, a field insulating film in contact with the second sidewall of the active pattern, a source/drain pattern disposed on the active pattern and in contact with the active pattern and the channel separation structure, a gate structure disposed on the active pattern and in contact with the channel separation structure, a first lower pattern disposed in an alignment mark area and including a plurality of sub-fin type patterns, and an alignment mark pattern including a plurality of lower alignment insulating patterns disposed between adjacent sub-fin type patterns and an upper alignment insulating pattern disposed on the lower alignment insulating patterns, wherein the upper alignment insulating pattern is in direct contact with each of the lower alignment insulating patterns.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view for describing a semiconductor device according to some example embodiments.

FIG. 2 is a layout view of a logic cell area of FIG. 1.

FIG. 3 is a layout view of an alignment mark of FIG. 1.

FIGS. 4 to 7 are cross-sectional views taken along lines A-A, B-B, C-C, and D-D of FIG. 2.

FIG. 8 is a view for describing a shape of a first sheet pattern of FIG. 4.

FIG. 9 is a view illustrating a schematic plan view of portion P of FIG. 2.

FIG. 10 is an enlarged view of portion Q of FIG. 6.

FIG. 11 is an enlarged view of portion S of FIG. 7.

FIG. 12 is a cross-sectional view taken along line E-E of FIG. 3.

FIG. 13 is a cross-sectional view taken along lines F-F and G-G of FIG. 3.

FIG. 14 is a cross-sectional view taken along line H-H of FIG. 3.

FIGS. 15 to 17 are views for describing a semiconductor device according to some example embodiments.

FIGS. 18 to 22 are views for describing a semiconductor device according to some example embodiments.

FIGS. 23 and 24 are views for describing a semiconductor device according to some example embodiments.

FIGS. 25 and 26 are views for describing a semiconductor device according to some example embodiments.

FIGS. 27 to 59 are intermediate step views for describing a method for manufacturing a semiconductor device according to some example embodiments.

### DETAILED DESCRIPTION OF THE EMBODIMENTS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. As used herein, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

In the drawings of a semiconductor device according to some example embodiments, a fin-type transistor (FinFET) including a channel region having a fin-type pattern shape, a transistor including nanowires or nanosheets, a multi-bridge channel field effect transistor (MBCFET™), or vertical FET is exemplarily illustrated, but the present disclosure is not limited thereto. The semiconductor device according to some example embodiments may include a tunneling FET or a three-dimensional (3D) transistor. The semiconductor device according to some example embodiments may include a planar transistor. In addition, a technical idea of the present disclosure may be applied to two-dimensional (2D) material-based FETs and a heterostructure thereof.

In addition, the semiconductor device according to some example embodiments may also include a bipolar junction transistor, a lateral double-diffused metal oxide semiconductor (LDMOS) transistor, or the like.

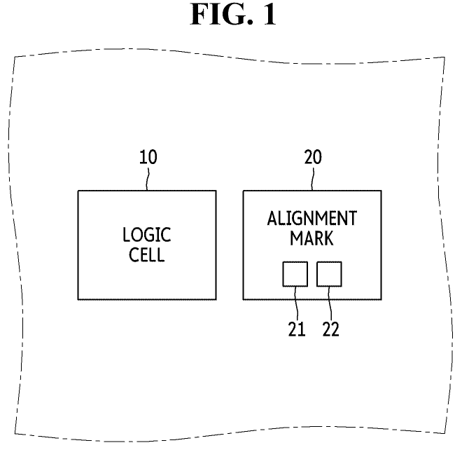

A semiconductor device according to some example embodiments will be described with reference to FIGS. 1 to 14.

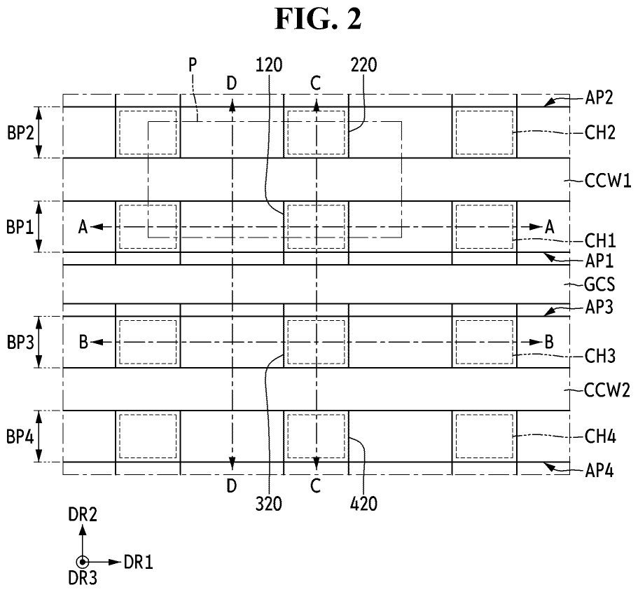

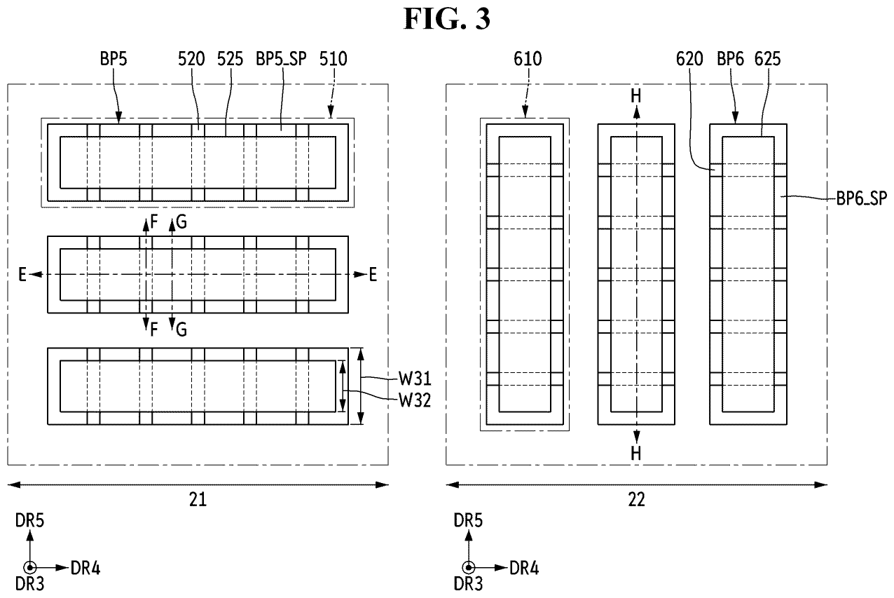

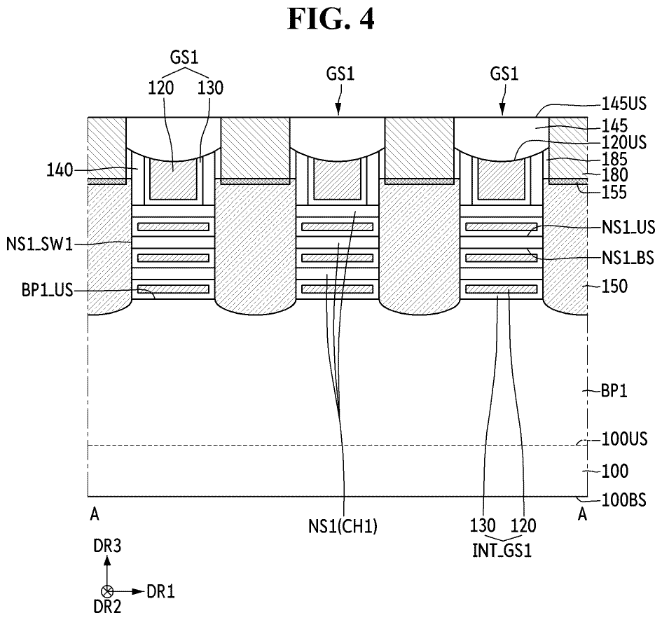

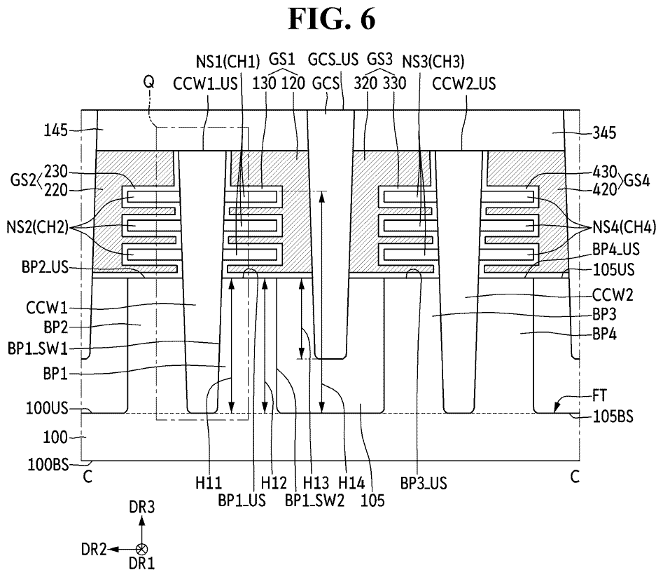

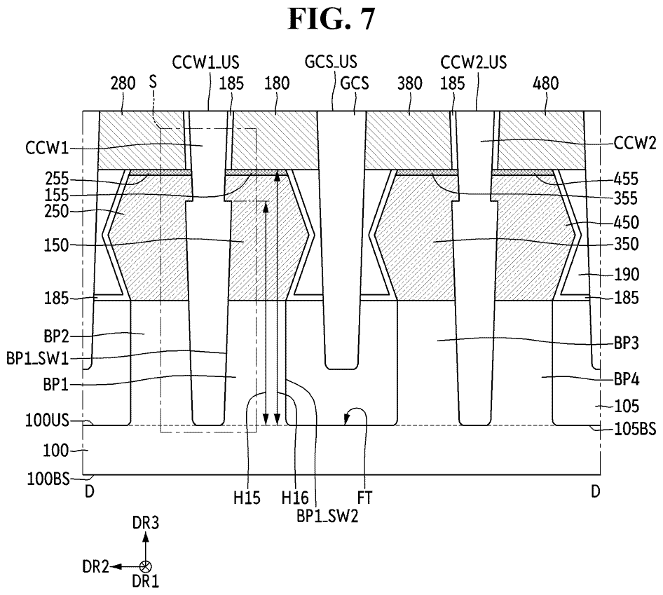

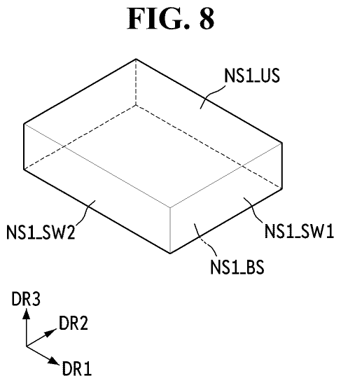

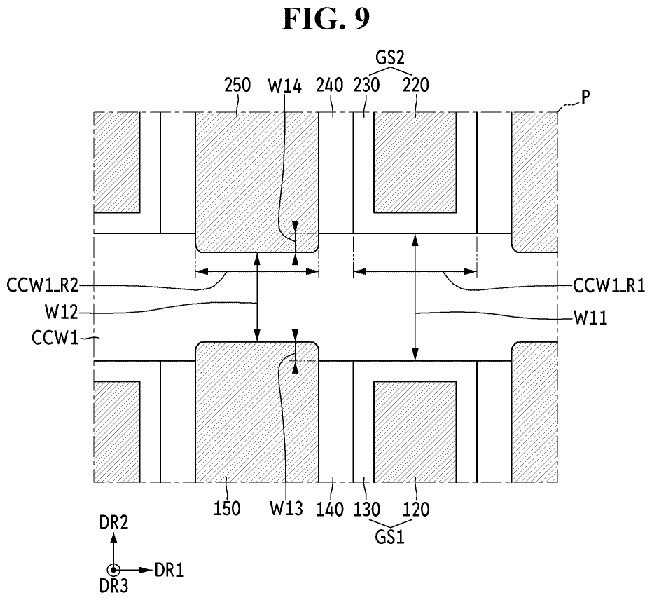

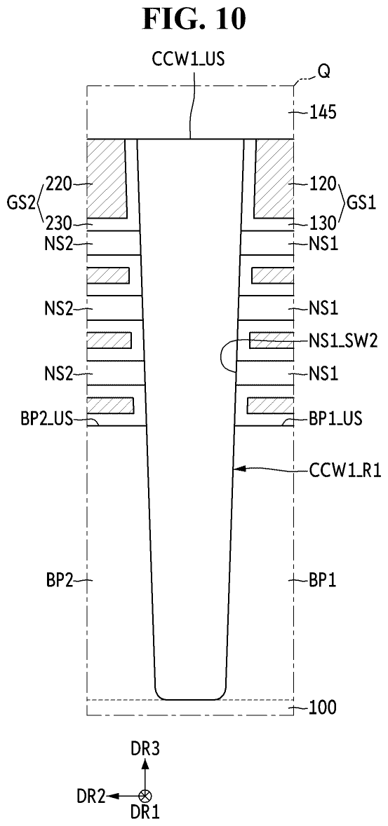

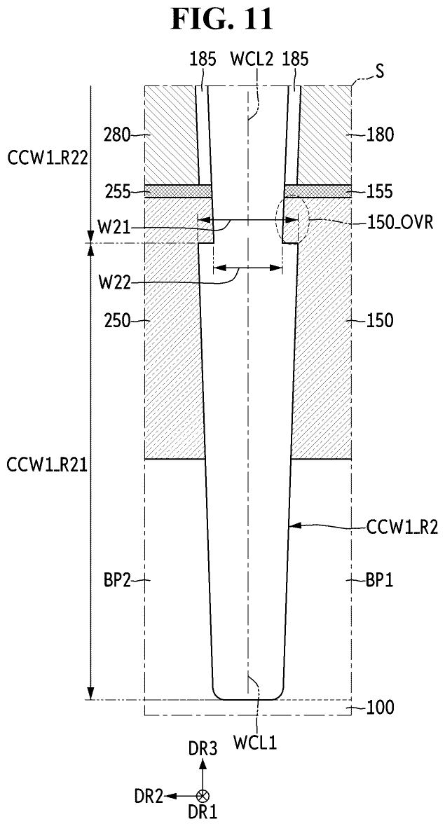

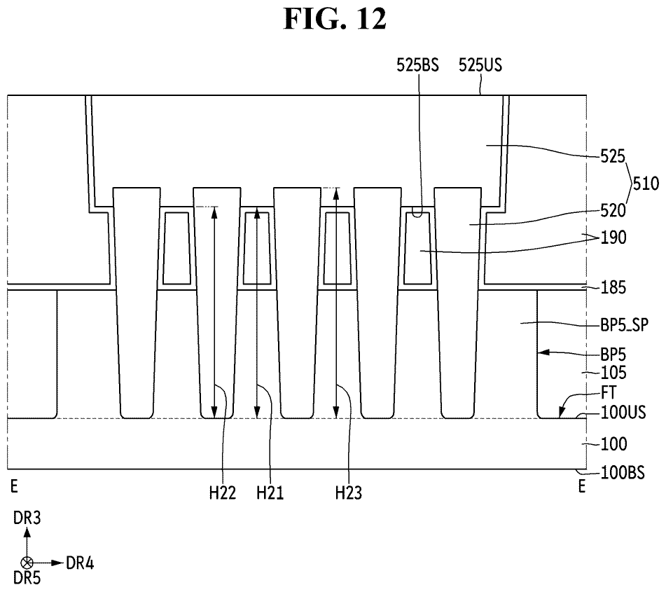

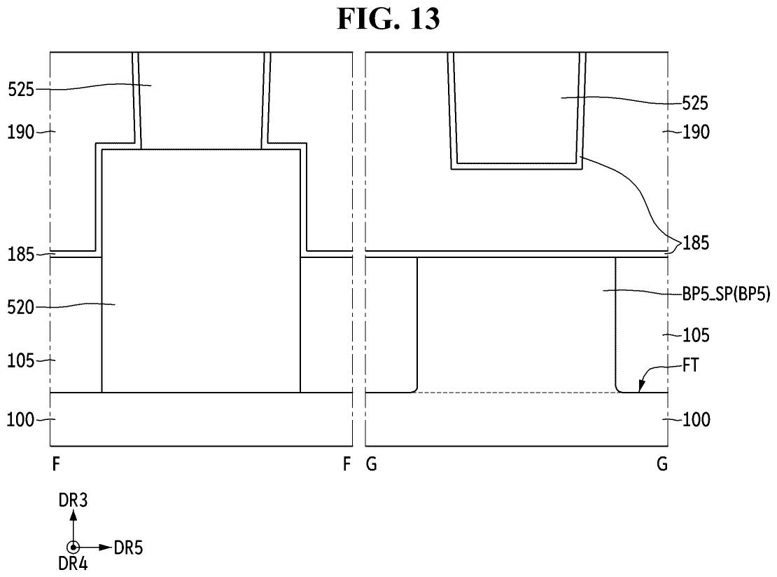

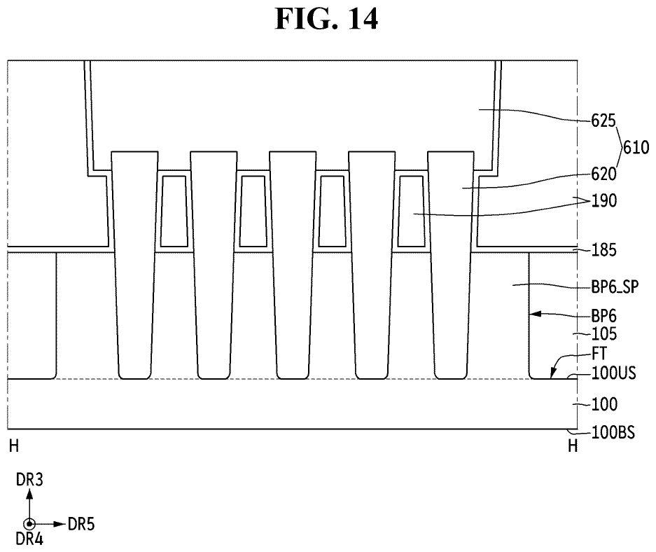

FIG. 1 is a layout view for describing a semiconductor device according to some example embodiments. FIG. 2 is a layout view of a logic cell area of FIG. 1. FIG. 3 is a layout view of an alignment mark of FIG. 1. FIGS. 4 to 7 are cross-sectional views taken along lines A-A, B-B, C-C, and D-D of FIG. 2. FIG. 8 is a view for describing a shape of a first sheet pattern of FIG. 4. FIG. 9 is a view illustrating a schematic plan view of portion P of FIG. 2. FIG. 10 is an enlarged view of portion Q of FIG. 6. FIG. 11 is an enlarged view of portion S of FIG. 7. FIG. 12 is a cross-sectional view taken along line E-E of FIG. 3. FIG. 13 is a cross-sectional view taken along lines F-F and G-G of FIG. 3. FIG. 14 is a cross-sectional view taken along line H-H of FIG. 3.

For reference, FIG. 2 is illustrated excluding source/drain contacts 180, 280, 380, and 480. In addition, FIG. 9 may be a plan view cut between the source/drain contacts 180 and 280 and sheet patterns NS1 and NS2 disposed at the uppermost portion.

Referring to FIGS. 1 to 14, a semiconductor device according to some example embodiments may include a logic cell area 10 and an alignment mark area 20.

In the logic cell area 10, a first lower pattern BP1, a second lower pattern BP2, a third lower pattern BP3, a fourth lower pattern BP4, a first channel pattern CH1, a second channel pattern CH2, a third channel pattern CH3, a fourth channel pattern CH4, a first channel separation structure CCW1, a second channel separation structure CCW2, a first gate electrode 120, a second gate electrode 220, a third gate electrode 320, a fourth gate electrode 420, a first source/drain pattern 150, a second source/drain pattern 250, a third source/drain pattern 350, a fourth source/drain pattern 450, and a gate separation structure GCS may be disposed.

A first substrate 100 may include a first surface 100US and a second surface 100BS that are opposite to each other in a third direction DR3. Since the first to fourth gate electrodes 120, 220, 320, and 420, the first to fourth source/drain patterns 150, 250, 350, and 450, and the channel patterns CH1, CH2, CH3, and CH4 may be disposed on the first surface 100US of the first substrate 100, the first surface 100US of the first substrate 100 may be an upper surface of the first substrate 100. The second surface 100BS of the first substrate 100 opposite to the first surface 100US of the first substrate 100 may be a bottom surface of the first substrate 100. For example, the first substrate 100 may be a base film on which the logic cell area 10 and the alignment mark area 20 are disposed.

The first substrate 100 may be made of a semiconductor material or may include a semiconductor material. The first substrate 100 may be a silicon substrate or a silicon-on-insulator (SOI) substrate. Unlike this, the first substrate 100 may, for example, include silicon germanium, silicon germanium on insulator (SGOI), indium antimonide, a lead tellurium compound, indium arsenide, indium phosphide, gallium arsenide, or gallium antimonide, but is not limited thereto.

Each of the first lower pattern BP1 and the second lower pattern BP2 may protrude in the third direction DR3 from the first substrate 100. The first lower pattern BP1 and the second lower pattern BP2 may protrude from the first surface 100US of the first substrate 100. Each of the first lower pattern BP1 and the second lower pattern BP2 may extend lengthwise in a first direction DR1. The first lower pattern BP1 and the second lower pattern BP2 may be spaced apart from each other in a second direction DR2.

Each of the third lower pattern BP3 and the fourth lower pattern BP4 may protrude in the third direction DR3 from the first substrate 100. The third lower pattern BP3 and the fourth lower pattern BP4 may protrude from the first surface 100US of the first substrate 100. Each of the third lower pattern BP3 and the fourth lower pattern BP4 may extend lengthwise in the first direction DR1. The third lower pattern BP3 and the fourth lower pattern BP4 may be spaced apart from each other in the second direction DR2.

For example, the third direction DR3 may be a thickness direction of the first substrate 100. For example, the third direction DR3 may be perpendicular to the first surface 100US and the second surface 100BS of the first substrate 100. The first direction DR1 and the second direction DR2 may each be perpendicular to the third direction DR3. For example, the first direction DR1 and the second direction DR2 may each be parallel to the first surface 100US of the first substrate 100. The first direction DR1 may be perpendicular to the second direction DR2.

The first lower pattern BP1 and the third lower pattern BP3 may be disposed between the second lower pattern BP2 and the fourth lower pattern BP4. The first lower pattern BP1 may be disposed between the second lower pattern BP2 and the third lower pattern BP3. The third lower pattern BP3 may be disposed between the first lower pattern BP1 and the fourth lower pattern BP4.

The first lower pattern BP1 and the third lower pattern BP3 may be separated by a fin trench extending in the first direction DR1. For example, the first surface 100US of the first substrate 100 may be a bottom surface of the fin trench FT.

The first lower pattern BP1 will be described as an example. The first lower pattern BP1 may include a first sidewall BP1_SW1 and a second sidewall BP1_SW2 that are opposite to each other in the second direction DR2. The first sidewall BP1_SW1 of the first lower pattern and the second sidewall BP1_SW2 of the first lower pattern may extend in the first direction DR1. The second sidewall BP1_SW2 of the first lower pattern may be defined by the fin trench FT. The first sidewall BP1_SW1 of the first lower pattern is not defined by the fin trench FT.

The second to fourth lower patterns BP2, BP3, and BP4 may include first sidewalls and second sidewalls that are opposite in the second direction DR2 like the first lower pattern BP1. For example, since the second sidewall BP1_SW2 of the first lower pattern and the second sidewall of the third lower pattern BP3 are defined by the fin trench FT, the second sidewall BP1_SW2 of the first lower pattern may face the second sidewall of the third lower pattern BP3.

The first lower pattern BP1 and the second lower pattern BP2 may be disposed in an area where a transistor of the same conductive type is formed. The third lower pattern BP3 and the fourth lower pattern BP4 may be disposed in an area where a transistor of the same conductive type is formed. As an example, the first lower pattern BP1 may be disposed in a PMOS formation area, and the third lower pattern BP3 may be disposed in an NMOS formation area. As another example, the first lower pattern BP1 and the third lower pattern BP3 may be disposed in a PMOS formation area. As still another example, the first lower pattern BP1 and the third lower pattern BP3 may be disposed in an NMOS formation area.

Each of the first to fourth lower patterns BP1, BP2, BP3, and BP4 may be formed by etching a portion of the first substrate 100 or may include an epitaxial layer grown from the first substrate 100. Each of the first to fourth lower patterns BP1, BP2, BP3, and BP4 may include silicon or germanium, which is an elemental semiconductor material. In addition, each of the first to fourth lower patterns BP1, BP2, BP3, and BP4 may include a compound semiconductor, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element.

The III-V compound semiconductor may be, for example, one of a binary compound, a ternary compound, or a quaternary compound formed by combining at least one of aluminum (Al), gallium (Ga), and indium (In), which are group III elements, and one of phosphorus (P), arsenic (As), and antimony (Sb), which are group V elements.

The first lower pattern BP1 and the second lower pattern BP2 include the same material. The third lower pattern BP3 and the fourth lower pattern BP4 include the same material.

The field insulating film 105 may be disposed on the first surface 100US of the first substrate 100. The field insulating film 105 may fill at least a portion of the fin trench FT separating the first lower pattern BP1 and the third lower pattern BP3.

From a cross-sectional perspective, the first lower pattern BP1 and the second lower pattern BP2 may be disposed between the field insulating films 105 adjacent to each other in the second direction DR2. The third lower pattern BP3 and the fourth lower pattern BP4 may be disposed between the field insulating films 105 adjacent to each other in the second direction DR2.

The field insulating film 105 is not disposed on an upper surface BP1_US of the first lower pattern, an upper surface BP2_US of the second lower pattern, an upper surface BP3_US of the third lower pattern BP3, and an upper surface BP4_US of the fourth lower pattern BP4.

The field insulating film 105 may be disposed on the second sidewall BP1_SW2 of the first lower pattern and the second sidewall of the third lower pattern BP3. The field insulating film 105 may be in contact with the second sidewall BP1_SW2 of the first lower pattern and the second sidewall of the third lower pattern BP3. As an example, the field insulating film 105 may entirely cover the second sidewall BP1_SW2 of the first lower pattern and the second sidewall of the third lower pattern BP3. Unlike illustrated, as another example, the field insulating film 105 may cover a portion of the second sidewall BP1_SW2 of the first lower pattern and a portion of the second sidewall of the third lower pattern BP3.

The field insulating film 105 may include an upper surface 105US and a bottom surface 105BS opposite to each other in the third direction DR3. The bottom surface 105BS of the field insulating film 105 may face the first substrate 100. For example, the bottom surface 105BS of the field insulating film 105 may be in contact with the first substrate 100. For example, the bottom surface 105BS of the field insulating film 105 may be in contact with the first surface 100US of the first substrate 100.

Although it is illustrated that the upper surface 105US of the field insulating film 105 has a flat shape, this is merely for convenience of explanation and the present disclosure is not limited thereto. The field insulating film 105 may include, for example, an oxide film, a nitride film, an oxynitride film, or a combination thereof. Although it is illustrated that the field insulating film 105 is a single film, this is merely for convenience of explanation and the present disclosure is not limited thereto.

The plurality of first channel patterns CH1 may be disposed on the first lower pattern BP1. Each first channel pattern CH1 may overlap the first lower pattern BP1 in the third direction DR3. The plurality of first channel patterns CH1 may be aligned in the first direction DR1.

The first active pattern AP1 may include a first lower pattern BP1 and a plurality of first channel patterns CH1. For example, the sidewalls BP1_SW1 and BP1_SW2 of the first lower pattern may be a sidewall of the first active pattern AP1. The first lower pattern BP1 may include the sidewall of the first active pattern AP1.

The plurality of second channel patterns CH2 may be disposed on the second lower pattern BP2. Each second channel pattern CH2 may overlap the second lower pattern BP2 in the third direction DR3. The plurality of second channel patterns CH2 may be aligned in the first direction DR1. The second channel pattern CH2 may be disposed to correspond to the first channel pattern CH1. The first channel pattern CH1 and the second channel pattern CH2 corresponding to each other may be spaced apart from each other in the second direction DR2. For example, each of the first channel patterns CH1 may be aligned with a corresponding one of the second channel patterns CH2 in the second direction DR2. The second active pattern AP2 may include a second lower pattern BP2 and a plurality of second channel patterns CH2.

The plurality of third channel patterns CH3 may be disposed on the third lower pattern BP3. Each third channel pattern CH3 may overlap the third lower pattern BP3 in the third direction DR3. The plurality of third channel patterns CH3 may be aligned in the first direction DR1. The third active pattern AP3 may include a third lower pattern BP3 and a plurality of third channel patterns CH3.

The plurality of fourth channel patterns CH4 may be disposed on the fourth lower pattern BP4. Each fourth channel pattern CH4 may overlap the fourth lower pattern BP4 in the third direction DR3. The plurality of fourth channel patterns CH4 may be aligned in the first direction DR1. The fourth channel pattern CH4 may be disposed to correspond to the third channel pattern CH3. The third channel pattern CH3 and the fourth channel pattern CH4 corresponding to each other may be spaced apart from each other in the second direction DR2. For example, each of the third channel patterns CH3 may be aligned with a corresponding one of the fourth channel patterns CH4 in the second direction DR2. The fourth active pattern AP4 may include a fourth lower pattern BP4 and a plurality of fourth channel patterns CH4.

Each of the first channel pattern CH1, the second channel pattern CH2, the third channel pattern CH3, and the fourth channel pattern CH4 may include a plurality of sheet patterns spaced apart from each other in the third direction DR3. Although it is illustrated that each of the first channel pattern CH1, the second channel pattern CH2, the third channel pattern CH3, and the fourth channel pattern CH4 include three sheet patterns, this is merely for convenience of explanation and the present disclosure is not limited thereto.

The first channel pattern CH1 may include a plurality of first sheet patterns NS1. The plurality of first sheet patterns NS1 may be disposed on the upper surface BP1_US of the first lower pattern BP1. The plurality of first sheet patterns NS1 may be arranged in the third direction DR3 on the first lower pattern BP1. The respective first sheet patterns NS1 may be spaced apart from each other in the third direction DR3. Each first sheet pattern NS1 includes an upper surface NS1_US and a bottom surface NS1_BS opposite to each other in the third direction DR3. For example, the upper surface NS1_US of the first sheet pattern disposed at the uppermost portion may be the upper surface of the first channel pattern CH1.

The third channel pattern CH3 may include a plurality of third sheet patterns NS3. The plurality of third sheet patterns NS3 may be disposed on the upper surface BP3_US of the third lower pattern BP3. The plurality of third sheet patterns NS3 may be arranged in the third direction DR3 on the third lower pattern BP3. The respective third sheet patterns NS3 may be spaced apart from each other in the third direction DR3. Each third sheet pattern NS3 includes an upper surface NS3_US and a bottom surface NS3_BS opposite to each other in the third direction DR3.

The second channel pattern CH2 may include a plurality of second sheet patterns NS2. The plurality of second sheet patterns NS2 may be disposed on the upper surface BP2_US of the second lower pattern BP2. The fourth channel pattern CH4 may include a plurality of fourth sheet patterns NS4. The plurality of fourth sheet patterns NS4 may be disposed on the upper surface BP4_US of the fourth lower pattern BP4.

The first sheet pattern NS1 will be described as an example. The first sheet pattern NS1 may include first sidewalls NS1_SW1 opposite to each other in the first direction DR1 and second sidewalls NS1_SW2 opposite to each other in the second direction DR2

t. The upper surface NS1_US of the first sheet pattern and the lower surface NS1_BS of the first sheet pattern may be connected by the first sidewall NS1_SW1 of the first sheet pattern and the second sidewall NS1_SW2 of the first sheet pattern. The first sidewall NS1_SW1 of the first sheet pattern is connected to and in contact with a first source/drain pattern 150 to be described later. The description regarding the first sheet pattern NS1 may also be applied to the second to fourth sheet patterns NS2, NS3, and NS4.

Each of the first to fourth sheet patterns NS1, NS2, NS3, and NS4 may include one of silicon or germanium, which is an elemental semiconductor material, a group IV-IV compound semiconductor, or a group III-V compound semiconductor. The first sheet pattern NS1 and the second sheet pattern NS2 may also include the same material as the first lower pattern BP1 or a material different from that of the first lower pattern BP1. The third sheet pattern NS3 and the fourth sheet pattern NS4 may also include the same material as the third lower pattern BP3 or a material different from that of the third lower pattern BP3.

In the semiconductor device according to some example embodiments, each of the first to fourth lower patterns BP1, BP2, BP3, and BP4 may be a silicon lower pattern including silicon. Each of the first to fourth sheet patterns NS1, NS2, NS3, and NS4 may be a silicon sheet pattern including silicon.

The first channel separation structure CCW1 may be disposed on the first surface 100US of the first substrate 100. The first channel separation structure CCW1 may be disposed between the first lower pattern BP1 and the second lower pattern BP2. The first channel separation structure CCW1 may extend lengthwise in the first direction DR1.

The first channel separation structure CCW1 may separate the first lower pattern BP1 and the second lower pattern BP2. The first channel separation structure CCW1 separates the first channel pattern CH1 and the second channel pattern CH2. The first lower pattern BP1 and the second lower pattern BP2 cover a portion of a sidewall of the first channel separation structure CCW1. The sidewall of the first channel separation structure CCW1 may extend in the first direction DR1.

The first channel separation structure CCW1 may be in contact with the first lower pattern BP1 and the second lower pattern BP2. The first channel separation structure CCW1 may be in contact with the first sidewall BP1_SW1 of the first lower pattern and the first sidewall of the second lower pattern BP2.

The first channel pattern CH1 and the second channel pattern CH2 may be in contact with the first channel separation structure CCW1. The plurality of first sheet patterns NS1 and the plurality of second sheet patterns NS2 may be in contact with the first channel separation structure CCW1. The first sheet pattern NS1 and the second sheet pattern NS2 may protrude from the sidewall of the first channel separation structure CCW1 in the second direction DR2. The first sheet pattern NS1 will be described as an example. One of the second sidewalls NS1_SW2 of the first sheet pattern may be in contact with the first channel separation structure CCW1. One of the second sidewalls of the second sheet pattern NS2 may be in contact with the first channel separation structure CCW1.

The second channel separation structure CCW2 may be disposed on the first surface 100US of the first substrate 100. The second channel separation structure CCW2 may be disposed between the third lower pattern BP3 and the fourth lower pattern BP4. The second channel separation structure CCW2 may extend lengthwise in the first direction DR1. The second channel separation structure CCW2 is spaced apart from the first channel separation structure CCW1 in the second direction DR2.

The second channel separation structure CCW2 may separate the third lower pattern BP3 and the fourth lower pattern BP4. The second channel separation structure CCW2 separates the third channel pattern CH3 and the fourth channel pattern CH4. The third lower pattern BP3 and the fourth lower pattern BP4 cover a portion of a sidewall of the second channel separation structure CCW2. The sidewall of the second channel separation structure CCW2 may extend in the first direction DR1.

The second channel separation structure CCW2 may be in contact with the third lower pattern BP3 and the fourth lower pattern BP4. The second channel separation structure CCW2 may be in contact with the first sidewall of the third lower pattern BP3 and the first sidewall of the fourth lower pattern BP4.

The third channel pattern CH3 and the fourth channel pattern CH4 may be in contact with the second channel separation structure CCW2. The plurality of third sheet patterns NS3 and the plurality of fourth sheet patterns NS4 may be in contact with the second channel separation structure CCW2. The third sheet pattern NS3 and the fourth sheet pattern NS4 may protrude from the sidewall of the second channel separation structure CCW2 in the second direction DR2. One of the second sidewalls of the third sheet pattern NS3 may be in contact with the second channel separation structure CCW2. One of the second sidewalls of the fourth sheet pattern NS4 may be in contact with the second channel separation structure CCW2.

The first channel separation structure CCW1 and the second channel separation structure CCW2 each include an insulating material. The first channel separation structure CCW1 and the second channel separation structure CCW2 may each include, for example, at least one of silicon nitride, silicon oxynitride, silicon oxide, silicon oxycarbonitride, silicon boron nitride, silicon oxyboron nitride, silicon oxycarbonate, aluminum oxide, and combinations thereof. Although the first channel separation structure CCW1 and the second channel separation structure CCW2 are each illustrated as a single film, this is merely for convenience of explanation and the present disclosure is not limited thereto. Since the first channel separation structure CCW1 and the second channel separation structure CCW2 are simultaneously formed, the first channel separation structure CCW1 and the second channel separation structure CCW2 include the same material.

Since the description of the second channel separation structure CCW2 may be substantially the same as the description of the first channel separation structure CCW1, the description of the first channel separation structure CCW1 may be applied to the second channel separation structure CCW2. A shape of the first channel separation structure CCW1 will be described in detail later.

In the semiconductor device according to some example embodiments, a depth H11 from the upper surface BP1_US of the first lower pattern to the lowest portion of the first channel separation structure CCW1 may be equal to or greater than a depth H12 from the upper surface BP1_US of the first lower pattern to the bottom surface 105BS of the field insulating film 105.

The gate separation structure GCS may be disposed on the first surface 100US of the first substrate 100. The gate separation structure GCS may extend lengthwise in the first direction DR1. The gate separation structure GCS may be disposed on the field insulating film 105. A portion of the gate separation structure GCS may be disposed within the upper interlayer insulating film 190.

The gate separation structure GCS may be in contact with the field insulating film 105. The gate separation structure GCS may protrude more in the third direction DR3 than the upper surface 105US of the field insulating film 105. For example, a portion of the gate separation structure GCS may be recessed into the field insulating film 105. For example, a lower surface of the gate separation structure GCS may be at a lower level than an upper surface 105US of the field insulating film 105.

The gate separation structure GCS is disposed between the first channel separation structure CCW1 and the second channel separation structure CCW2. The first to fourth channel patterns CH1, CH2, CH3, and CH4 are disposed between the channel separation structures CCW1 and CCW2 and the gate separation structure GCS.

For example, the depth H11 from the upper surface BP1_US of the first lower pattern BP1 to the lowest portion of the first channel separation structure CCW1 may be greater than a depth H13 from the upper surface BP1_US of the first lower pattern BP1 to the lowest portion of the gate separation structure GCS.

The gate separation structure GCS includes an insulating material. The gate separation structure GCS may include, for example, at least one of silicon nitride, silicon oxynitride, silicon oxide, silicon oxycarbonitride, silicon boron nitride, silicon oxyboron nitride, silicon oxycarbide, aluminum oxide, and combinations thereof. Although the gate separation structure GCS is illustrated as a single film, this is merely for convenience of explanation and the present disclosure is not limited thereto.

First to fourth gate structures GS1, GS2, GS3, and GS4 may be disposed on the first surface 100US of the first substrate 100. The first to fourth gate structures GS1, GS2, GS3, and GS4 may be in contact with the upper surface 105US of the field insulating film 105.

A plurality of first gate structures GS1 may be disposed between the first channel separation structure CCW1 and the gate separation structure GCS. The plurality of first gate structures GS1 may be in contact with the first channel separation structure CCW1 and the gate separation structure GCS. The first gate structures GS1 may be adjacent to each other in the first direction DR1.

The first gate structure GS1 may be disposed on the first lower pattern BP1. For example, the first gate structure GS1 may be in contact with the upper surface BP1_US of the first lower pattern. The first channel pattern CH1 may be disposed between the first gate structure GS1 and the first channel separation structure CCW1. Each first sheet pattern NS1 may be disposed between the first gate structure GS1 and the first channel separation structure CCW1. Since each first sheet pattern NS1 is in contact with the first channel separation structure CCW1, the first gate structure GS1 does not surround each first sheet pattern NS1 in a cross-sectional perspective.

The first gate structure GS1 may include a first gate electrode 120 and a first gate insulating film 130. The first gate electrode 120 may be disposed on the first lower pattern BP1. The first gate insulating film 130 may be disposed between the first gate electrode 120 and the first channel pattern CH1. For example, the first gate insulating film 130 may be disposed between the first gate electrode 120 and the first sheet pattern NS1.

The first gate insulating film 130 may extend along the upper surface 105US of the field insulating film 105 and the upper surface BP1_US of the first lower pattern BP1. The first gate insulating film 130 may be in contact with the upper surface 105US of the field insulating film 105 and the upper surface BP1_US of the first lower pattern BP1. From a cross-sectional perspective such as FIG. 6, the first gate insulating film 130 may extend along the sidewall of the first channel separation structure CCW1. The first gate electrode 120 is not in contact with the sidewall of the first channel separation structure CCW1. The first gate insulating film 130 does not extend along the sidewall of the gate separation structure GCS. The first gate electrode 120 may be in contact with the sidewall of the gate separation structure GCS. The first gate insulating film 130 may be disposed along a portion of a circumference of the first sheet pattern NS1.

The first gate structure GS1 may include a first inner gate structure INT_GS1. The first inner gate structure INT_GS1 may be disposed between the first lower pattern BP1 and the first sheet pattern NS1, and between the first sheet patterns NS1 adjacent to each other in the third direction DR3. The first gate insulating film 130 included in the first inner gate structure INT_GS1 may be in contact with a first source/drain pattern 150 to be described later.

Since the description of the second to fourth gate structures GS2, GS3, and GS4 may be substantially the same as the description of the first gate structure GS1 described above, the second to fourth gate structures GS2, GS3, and GS4 will be briefly described.

A plurality of second gate structures GS2 may be disposed between the first channel separation structure CCW1 and the gate separation structure GCS. The plurality of second gate structures GS2 may be in contact with the first channel separation structure CCW1 and the gate separation structure GCS. The first channel separation structure CCW1 may be disposed between the first gate structure GS1 and the second gate structure GS2. The second gate structures GS2 may be adjacent to each other in the first direction DR1. The second gate structure GS2 may be spaced apart from the first gate structure GS1 in the second direction DR2.

The second gate structure GS2 may be disposed on the second lower pattern BP2. For example, the second gate structure GS2 may be in contact with the upper surface BP2_US of the second lower pattern BP2. The second channel pattern CH2 may be disposed between the second gate structure GS2 and the first channel separation structure CCW1. The second gate structure GS2 may include a second gate electrode 220 and a second gate insulating film 230. The second gate structure GS2 may include a second inner gate structure disposed between the second lower pattern BP2 and the second sheet pattern NS2, and between the second sheet patterns NS2 adjacent to each other in the third direction DR3.

A plurality of third gate structures GS3 may be disposed between the second channel separation structure CCW2 and the gate separation structure GCS. The plurality of third gate structures GS3 may be in contact with the second channel separation structure CCW2 and the gate separation structure GCS. The third gate structures GS3 may be adjacent to each other in the first direction DR1. The third gate structure GS3 may be spaced apart from the first gate structure GS1 in the second direction DR2.

The third gate structure GS3 may be disposed on the third lower pattern BP3. For example, the third gate structure GS3 may be in contact with the upper surface BP3_US of the third lower pattern BP3. The third channel pattern CH3 may be disposed between the third gate structure GS3 and the second channel separation structure CCW2. The third gate structure GS3 may include a third gate electrode 320 and a third gate insulating film 330. The third gate structure GS3 may include a third inner gate structure INT_GS3 disposed between the third lower pattern BP3 and the third sheet pattern NS3, and between the third sheet patterns NS3 adjacent to each other in the third direction DR3. The third gate insulating film 330 included in the third inner gate structure INT_GS3 may be in contact with a third source/drain pattern 350 to be described later.

A plurality of fourth gate structures GS4 may be disposed between the second channel separation structure CCW2 and the gate separation structure GCS. The plurality of fourth gate structures GS4 may be in contact with the second channel separation structure CCW2 and the gate separation structure GCS. The second channel separation structure CCW2 may be disposed between the third gate structure GS3 and the fourth gate structure GS4. The fourth gate structures GS4 may be adjacent to each other in the first direction DR1. The fourth gate structure GS4 may be spaced apart from the third gate structure GS3 in the second direction DR2.

The fourth gate structure GS4 may be disposed on the fourth lower pattern BP4. For example, the fourth gate structure GS4 may be in contact with the upper surface BP4_US of the fourth lower pattern BP4. The fourth channel pattern CH4 may be disposed between the fourth gate structure GS4 and the second channel separation structure CCW2. The fourth gate structure GS4 may include a fourth gate electrode 420 and a fourth gate insulating film 430. The fourth gate structure GS4 may include a fourth inner gate structure disposed between the fourth lower pattern BP4 and the fourth sheet pattern NS4, and between the fourth sheet patterns NS4 adjacent to each other in the third direction DR3.

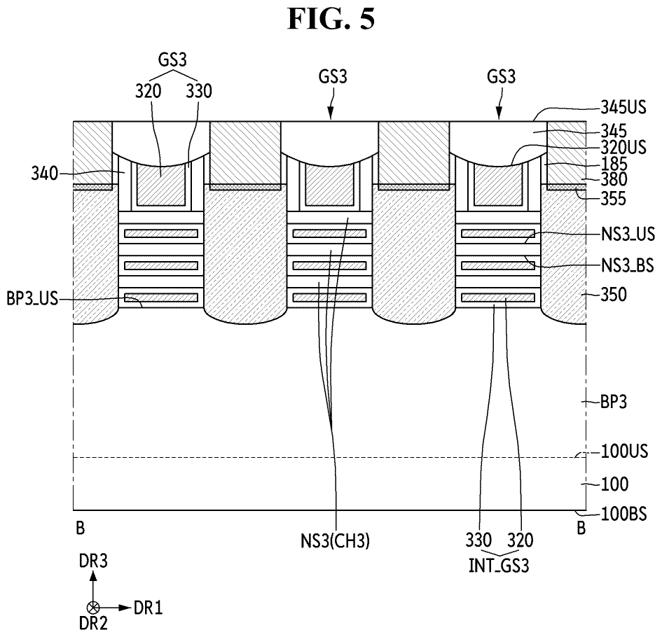

In the cross-sectional views such as FIGS. 4 and 5, an upper surface 120US of the first gate electrode and an upper surface 320US of the third gate electrode are illustrated as concave curved surfaces, but are not limited thereto. The upper surface 120US of the first gate electrode and the upper surface 320US of the third gate electrode may be a flat surface.

In the cross-sectional view such as FIG. 6, the upper surface of the first gate electrode 120 and an upper surface of the second gate electrode 220 may be a flat surface. The upper surface of the third gate electrode 320 and an upper surface of the fourth gate electrode 420 may be a flat surface.

The first to fourth gate electrodes 120, 220, 320, and 420 may include at least one of a metal, conductive metal nitride, metal silicide, a doped semiconductor material, conductive metal oxide, and conductive metal oxynitride. The first to fourth gate electrodes 120, 220, 320, and 420 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include an oxidized form of the above-described materials, but are not limited thereto.

The first to fourth gate insulating films 130, 230, 330, and 430 may include silicon oxide, silicon oxynitride, silicon nitride, or a high-k material having a dielectric constant greater than that of silicon oxide. The high-k material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

Although each of the first to fourth gate insulating films 130, 230, 330, and 430 is illustrated as a single film, this is merely for convenience of explanation and the present disclosure is not limited thereto. The first to fourth gate insulating films 130, 230, 330, and 430 may each include a plurality of films. The first gate insulating film 130 will be described as an example. The first gate insulating film 130 may include an interfacial layer disposed between the first channel pattern CH1 and the first gate electrode 120, and a high-k insulating film. For example, the interfacial layer may not be formed along a profile of the upper surface 105US of the field insulating film 105.

The semiconductor device according to some example embodiments may include a negative capacitance (NC) FET using a negative capacitor. For example, each of the first to fourth gate insulating films 130, 230, 330, and 430 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 m V/decade at room temperature by using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic % (at %) of aluminum. Here, a ratio of the dopant may be a ratio of aluminum to the sum of hafnium and aluminum.

When the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may contain 1 to 7 at % of gadolinium. When the dopant is zirconium (Zr), the ferroelectric material film may include 50 to 80 at % of zirconium.

The paraelectric material film may have the paraelectric characteristics. The paraelectric material film may include, for example, at least one of silicon oxide and metal oxide having a high dielectric constant. The metal oxide included in the paraelectric material film may include, but is not limited to, for example, at least one of hafnium oxide, zirconium oxide, and aluminum oxide.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include the hafnium oxide, a crystal structure of the hafnium oxide included in the ferroelectric material film is different from a crystal structure of the hafnium oxide included in the paraelectric material film.

The ferroelectric material film may have a thickness having the ferroelectric characteristics. The thickness of the ferroelectric material film may be, for example, 0.5 to 10 nm, but is not limited thereto. Since a critical thickness representing the ferroelectric characteristics may vary for each ferroelectric material, the thickness of the ferroelectric material film may vary depending on the ferroelectric material.

As an example, each of the first to fourth gate insulating films 130, 230, 330, and 430 may include one ferroelectric material film. As another example, each of the first to fourth gate insulating films 130, 230, 330, and 430 may include a plurality of ferroelectric material films spaced apart from each other. Each of the first to fourth gate insulating films 130, 230, 330, and 430 may have a stacked film structure in which a plurality of ferroelectric material films and a plurality of paraelectric material films are alternately stacked.

A first gate spacer 140 may be disposed on the sidewall of the first gate structure GS1. A third gate spacer 340 may be disposed on the sidewall of the third gate structure GS3. Although not illustrated, second and fourth gate spacers may be disposed on the sidewall of the second gate structure GS2 and the sidewall of the fourth gate structure GS4, respectively.

For example, the first gate spacer 140 may not be disposed between the first lower pattern BP1 and the first sheet pattern NS1 and between the first sheet patterns NS1 adjacent to each other in the third direction DR3. The third gate spacer 340 may not be disposed between the third lower pattern BP3 and the third sheet pattern NS3 and between the third sheet patterns NS3 adjacent to each other in the third direction DR3.

Unlike illustrated, as an example, a first inner spacer may be disposed between the first lower pattern BP1 and the first sheet pattern NS1, and between the first sheet patterns NS1 adjacent to each other in the third direction DR3. In this case, the first gate insulating film 130 may not be in contact with the first source/drain pattern 150. As another example, a second inner spacer may be disposed between the third lower pattern BP3 and the third sheet pattern NS3, and between the third sheet patterns NS3 adjacent to each other in the third direction DR3. In this case, the third gate insulating film 330 may not be in contact with the third source/drain pattern 350. As still another example, the first inner spacer may be disposed between the first lower pattern BP1 and the first sheet pattern NS1, and between the first sheet patterns NS1 adjacent to each other in the third direction DR3. The second inner spacer may be disposed between the third lower pattern BP3 and the third sheet pattern NS3, and between the third sheet patterns NS3 adjacent to each other in the third direction DR3.

The first and third gate spacers 140 and 340 may include, for example, at least one of silicon nitride, silicon oxynitride, silicon oxide, silicon oxycarbonitride, silicon boron nitride, silicon oxyboron nitride, silicon oxycarbide, and combinations thereof. Although the first and third gate spacers 140 and 340 are illustrated as a single film, it is merely for convenience of explanation and the present disclosure is not limited thereto.

A first gate capping pattern 145 may be disposed on the first gate structure GS1 and the second gate structure GS2. The first gate capping pattern 145 may be disposed on the upper surface 120US of the first gate electrode and the upper surface of the second gate electrode 220. An upper surface 145US of the first gate capping pattern may be on the same plane as the upper surface GCS_US of the gate separation structure.

A second gate capping pattern 345 may be disposed on the third gate structure GS3 and the fourth gate structure GS4. The second gate capping pattern 345 may be disposed on the upper surface 320US of the third gate electrode and the upper surface of the fourth gate electrode 420. An upper surface 345US of the second gate capping pattern may be on the same plane as the upper surface GCS_US of the gate separation structure.

In the cross-sectional view such as FIG. 6, the first gate capping pattern 145 may be disposed on the first channel separation structure CCW1. The first gate capping pattern 145 may be disposed on an upper surface CCW1_US of the first channel separation structure. The second gate capping pattern 345 may be disposed on the second channel separation structure CCW2. The second gate capping pattern 345 may be disposed on an upper surface CCW2_US of the second channel separation structure. Based on the bottom surface 105BS of the field insulating film 105, the upper surface CCW1_US of the first channel separation structure may be lower than a height of the upper surface GCS_US of the gate separation structure. Based on the bottom surface 105BS of the field insulating film 105, the upper surface CCW2_US of the second channel separation structure may be lower than a height of the upper surface GCS_US of the gate separation structure.

The first gate capping pattern 145 and the second gate capping pattern 345 may include, for example, at least one of silicon nitride, silicon oxynitride, silicon carbonitride, silicon oxycarbonitride, and a combination thereof.

The first source/drain pattern 150 may be disposed on the first lower pattern BP1. The first source/drain pattern 150 may be disposed adjacent to the first gate structure GS1 in the first direction DR1. The first source/drain pattern 150 may be disposed between the first channel separation structure CCW1 and the gate separation structure GCS. The first source/drain pattern 150 is connected to the first channel pattern CH1. The first source/drain pattern 150 may be in contact with the first channel pattern CH1. For example, the first source/drain pattern 150 may be in contact with the first inner gate structure INT_GS1.

The second source/drain pattern 250 may be disposed on the second lower pattern BP2. The second source/drain pattern 250 may be disposed adjacent to the second gate structure GS2 in the first direction DR1. The second source/drain pattern 250 may be disposed between the first channel separation structure CCW1 and the gate separation structure GCS. Although not illustrated, the second source/drain pattern 250 is connected to the second channel pattern CH2.

The third source/drain pattern 350 may be disposed on the third lower pattern BP3. The third source/drain pattern 350 may be disposed adjacent to the third gate structure GS3 in the first direction DR1. The third source/drain pattern 350 may be disposed between the second channel separation structure CCW2 and the gate separation structure GCS. The third source/drain pattern 350 is connected to the third channel pattern CH3. The third source/drain pattern 350 may be in contact with the third channel pattern CH3. For example, the third source/drain pattern 350 may be in contact with the third inner gate structure INT_GS3.

The fourth source/drain pattern 450 may be disposed on the fourth lower pattern BP4. The fourth source/drain pattern 450 may be disposed adjacent to the fourth gate structure GS4 in the first direction DR1. The fourth source/drain pattern 450 may be disposed between the second channel separation structure CCW2 and the gate separation structure GCS. Although not illustrated, the fourth source/drain pattern 450 is connected to the fourth channel pattern CH4.

The first channel separation structure CCW1 may be disposed between the first source/drain pattern 150 and the second source/drain pattern 250. The first source/drain pattern 150 and the second source/drain pattern 250 are spaced apart from each other in the second direction DR2.

The first source/drain pattern 150 and the second source/drain pattern 250 may be in contact with the first channel separation structure CCW1. For example, the first source/drain pattern 150 and the second source/drain pattern 250 may be in contact with the sidewall of the first channel separation structure CCW1.

For example, a portion of the first source/drain pattern 150 may overlap the first channel separation structure CCW1 in the third direction DR3. The first source/drain pattern 150 may include an overlapping portion 150_OVR that overlaps the first channel separation structure CCW1 in the third direction DR3. A portion of the first source/drain pattern 150 may span the first channel separation structure CCW1. A portion of the second source/drain pattern 250 may overlap the first channel separation structure CCW1 in the third direction DR3. A portion of the second source/drain pattern 250 may span the first channel separation structure CCW1.

The second channel separation structure CCW2 may be disposed between the third source/drain pattern 350 and the fourth source/drain pattern 450. The third source/drain pattern 350 and the fourth source/drain pattern 450 are spaced apart from each other in the second direction DR2.

The third source/drain pattern 350 and the fourth source/drain pattern 450 may be in contact with the second channel separation structure CCW2. For example, the third source/drain pattern 350 and the fourth source/drain pattern 450 may be in contact with the sidewall of the second channel separation structure CCW2.

For example, a portion of the third source/drain pattern 350 and a portion of the fourth source/drain pattern 450 may overlap the second channel separation structure CCW2 in the third direction DR3. A portion of the third source/drain pattern 350 and a portion of the fourth source/drain pattern 450 may span the second channel separation structure CCW2.

The first to fourth source/drain patterns 150, 250, 350, and 450 may be disposed on the first surface 100US of the substrate. The first source/drain pattern 150 may be included in a source/drain of a transistor that uses the first sheet pattern NS1 as a channel region. The second source/drain pattern 250 may be included in a source/drain of a transistor that uses the second sheet pattern NS2 as a channel region. The third source/drain pattern 350 may be included in a source/drain of a transistor that uses the third sheet pattern NS3 as a channel region. The fourth source/drain pattern 450 may be included in a source/drain of a transistor that uses the fourth sheet pattern NS4 as a channel region.

Each of the first to fourth source/drain patterns 150, 250, 350, and 450 may include an epitaxial pattern. Each of the first to fourth source/drain patterns 150, 250, 350, and 450 may include a semiconductor material.

The first source/drain pattern 150 and the second source/drain pattern 250 may include dopants of the same conductivity type. The first source/drain pattern 150 and the second source/drain pattern 250 may include a p-type dopant or an n-type dopant. The third source/drain pattern 350 and the fourth source/drain pattern 450 may include dopants of the same conductivity type. The third source/drain pattern 350 and the fourth source/drain pattern 450 may include a p-type dopant or an n-type dopant. The p-type dopant may include at least one of boron (B) and gallium (Ga), but is not limited thereto. The n-type dopant may include at least one of phosphorus (P), arsenic (As), antimony (Sb), and bismuth (Bi), but is not limited thereto.

In the following description, the first channel separation structure CCW1 will be mainly described. That is, the description of the first channel separation structure CCW1 may be applied to the second channel separation structure CCW2.

In FIGS. 1, 4, 5, 7 to 9, the first channel separation structure CCW1 may include a first area CCW1_R1 and a second area CCW1_R2. The first area CCW1_R1 of the first channel separation structure may be an area that is in contact with the first gate structure GS1 and the second gate structure GS2 in the first channel separation structure CCW1. The first area CCW1_R1 of the first channel separation structure may be an area that overlaps the first gate structure GS1 and the second gate structure GS2 in the second direction DR2. The second area CCW1_R2 of the first channel separation structure may be an area that is in contact with the first source/drain pattern 150 and the second source/drain pattern 250 in the first channel separation structure CCW1. The second area CCW1_R2 of the first channel separation structure may be an area that overlaps the first source/drain pattern 150 and the second source/drain pattern 250 in the second direction DR2.

For example, FIG. 10 is a view for describing a shape of the first area CCW1_R1 of the first channel separation structure and FIG. 11 is a view for describing a shape of the second area CCW1_R2 of the first channel separation structure.

In FIGS. 6 and 10, a width of the first channel separation structure CCW1 in the second direction DR2 may continuously increase as a distance from the bottom surface 105BS of the field insulating film 105 increases.

In FIGS. 7 and 11, the second area CCW1_R2 of the first channel separation structure may include a first portion CCW1_R21 and a second portion CCW1_R22 whose width increases as a distance from the bottom surface 105BS of the field insulating film 105 increases. In the first portion CCW1_R21 of the second area of the first channel separation structure and the second portion CCW1_R22 of the second area of the first channel separation structure, the width of the first channel separation structure CCW1 in the second direction DR2 may continuously increase as the distance from the bottom surface 105BS of the field insulating film 105 increases.

The second portion CCW1_R22 of the second area of the first channel separation structure may be disposed on the first portion CCW1_R21 of the second area of the first channel separation structure. The second portion CCW1_R22 of the second area of the first channel separation structure may be directly connected to the first portion CCW1_R21 of the second area of the first channel separation structure. Unlike illustrated, the second area CCW1_R2 of the first channel separation structure may include an inserted portion between the first portion CCW1_R21 of the second area of the first channel separation structure and the second portion CCW1_R22 of the second area of the first channel separation structure. A width of the inserted portion of the second area CCW1_R2 of the first channel separation structure may decrease as a distance from the bottom surface 105BS of the field insulating film 105 increases.

There may be a step between the first portion CCW1_R21 of the second area of the first channel separation structure and the second portion CCW1_R22 of the second area of the first channel separation structure. In other words, a width W21 of the uppermost portion of the first channel separation structure CCW1 in the first portion CCW1_R21 of the second area of the first channel separation structure is greater than a width W22 of the lowermost portion of the first channel separation structure CCW1 in the second portion CCW1_R22 of the second area of the first channel separation structure.

The first portion CCW1_R21 of the second area of the first channel separation structure may include a first width centerline WCL1 extending in the third direction DR3. The second portion CCW1_R22 of the second area of the first channel separation structure may include a second width centerline WCL2 extending in the third direction DR3. For example, the first width centerline WCL1 may be aligned with the second width centerline WCL2 in the third direction DR3. In other words, an extension line of the first width centerline WCL1 may coincide with the second width centerline WCL2.

For example, the first width centerline WCL1 may be an imaginary line dividing the width W21 of the uppermost portion of the first portion CCW1_R21 of the second area of the first channel separation structure into half. The second width centerline WCL2 may be an imaginary line dividing the width W22 of the lowest portion of the second portion CCW1_R22 of the second area of the first channel separation structure into half.

Unlike illustrated, the first width centerline WCL1 may be spaced apart from the second width centerline WCL2 in the second direction DR2. The first width centerline WCL1 may be misaligned with the second width centerline WCL2 in the third direction DR3.

A height H15 from the bottom surface 105BS of the field insulating film 105 to the uppermost portion of the first portion CCW1_R21 of the second area of the first channel separation structure is smaller than a height H16 from the bottom surface 105BS of the field insulating film 105 to the uppermost portion of the first source/drain pattern 150.

Here, the uppermost portion of the first source/drain pattern 150 may be included in a structure including the first source/drain pattern 150 and a first contact silicide film 155. The uppermost portion of the first source/drain pattern 150 may be the portion furthest from the bottom surface 105BS of the field insulating film 105.

A portion of the first source/drain pattern 150 may overlap the first portion CCW1_R21 of the second area of the first channel separation structure in the third direction DR3. The overlapping portion 150_OVR of the first source/drain pattern may overlap the first portion CCW1_R21 of the second area of the first channel separation structure in the third direction DR3. The overlapping portion 150_OVR of the first source/drain pattern may span the first portion CCW1_R21 of the second area of the first channel separation structure.

A portion of the second source/drain pattern 250 may overlap the first portion CCW1_R21 of the second area of the first channel separation structure in the third direction DR3. A portion of the second source/drain pattern 250 may span the first portion CCW1_R21 of the second area of the first channel separation structure.

Although it is illustrated that there is no boundary surface between the first portion CCW1_R21 of the second area of the first channel separation structure and the second portion CCW1_R22 of the second area of the first channel separation structure, the present disclosure is not limited thereto. Unlike illustrated, the first portion CCW1_R21 of the second area of the first channel separation structure may be separated from the second portion CCW1_R22 of the second area of the first channel separation structure by the boundary surface.

In FIGS. 6 and 7, the height H15 from the bottom surface 105BS of the field insulating film 105 to the uppermost portion of the first portion CCW1_R21 of the second area of the first channel separation structure is smaller than a height H14 from the bottom surface 105BS of the field insulating film 105 to the upper surface of the first channel pattern CH1.

In the cross-sectional view such as FIG. 7, the upper surface CCW1_US of the first channel separation structure may be on the same plane as the upper surface GCS_US of the gate separation structure.

The upper surface CCW1_US of the first channel separation structure in the first area CCW1_R1 of the first channel separation structure may be lower than the upper surface CCW1_US of the first channel separation structure in the second area CCW1_R2 of the first channel separation structure. A height from the bottom surface 105BS of the field insulating film 105 to the upper surface CCW1_US of the first channel separation structure in the first area CCW1_R1 of the first channel separation structure may be smaller than a height from the bottom surface 105BS of the field insulating film 105 to the upper surface CCW1_US of the first channel separation structure in the second area CCW1_R2 of the first channel separation structure.

For example, FIG. 11 may be a plan view cut at a height level of the second portion CCW1_R22 of the second area of the first channel separation structure.

In FIG. 9, a width W11 of the first channel separation structure CCW1 in the second direction DR2 between the first gate structure GS1 and the second gate structure GS2 is different from a width W12 of the first channel separation structure CCW1 in the second direction DR2 between the first source/drain pattern 150 and the second source/drain pattern 250. For example, the width W11 of the first channel separation structure CCW1 in the second direction DR2 between the first gate structure GS1 and the second gate structure GS2 is greater than the width W12 of the first channel separation structure CCW1 in the second direction DR2 between the first source/drain pattern 150 and the second source/drain pattern 250.

The first source/drain pattern 150 may overlap the first channel separation structure CCW1 in the first direction DR1 by a first overlapping width W13. The second source/drain pattern 250 may overlap the first channel separation structure CCW1 in the first direction DR1 by a second overlapping width W14. For example, the first overlapping width W13 may be equal to the second overlapping width W14.

A source/drain etch stop film 185 may extend along outer sidewalls of the first and third gate spacers 140 and 340 and the sidewalls of the first to fourth source/drain patterns 150, 250, 350, and 450. The source/drain etch stop film 185 may extend along the upper surface 105US of the field insulating film 105. For example, the source/drain etch stop film 185 may be in contact with the sidewalls of the first to fourth source/drain patterns 150, 250, 350, and 450.

A portion of the source/drain etch stop film 185 may extend along the sidewall of the first channel separation structure CCW1 and the sidewall of the second channel separation structure CCW2. The source/drain etch stop film 185 on the sidewall of the first channel separation structure CCW1 and the sidewall of the second channel separation structure CCW2 may be a portion that remains and is not removed during a process of manufacturing the source/drain contacts 180, 280, 380, and 480.

The source/drain etch stop film 185 may not extend along a sidewall of the first gate capping pattern 145 and a sidewall of the second gate capping pattern 345. Unlike illustrated, the source/drain etch stop film 185 may also extend along the sidewall of the first gate capping pattern 145 and the sidewall of the second gate capping pattern 345.

The source/drain etch stop film 185 may include, for example, at least one of silicon nitride, silicon oxynitride, silicon oxycarbonitride, silicon boron nitride, silicon oxyboron nitride, silicon oxycarbide, and a combination thereof.

When the source/drain etch stop film 185 includes the same material as the first channel separation structure CCW1, a boundary between the source/drain etch stop film 185 and the first channel separation structure CCW1 may not be distinguished. When the source/drain etch stop film 185 includes the same material as the second channel separation structure CCW2, a boundary between the source/drain etch stop film 185 and the second channel separation structure CCW2 may not be distinguished. In this case, the source/drain etch stop film 185 disposed on the first to fourth source/drain patterns 150, 250, 350, and 450 and in contact with the first to fourth source/drain contacts 180, 280, 380, and 480 may be seen as portion of the first channel separation structure CCW1 and/or the second channel separation structure CCW2.

Unlike illustrated, the source/drain etch stop film 185 may not be formed.

The upper interlayer insulating film 190 is disposed on the first surface 100US of the substrate. The upper interlayer insulating film 190 may be disposed on the source/drain etch stop film 185. The upper interlayer insulating film 190 may be disposed on the first to fourth source/drain patterns 150, 250, 350, and 450.

The upper interlayer insulating film 190 may include, for example, at least one of silicon oxide, silicon nitride, silicon oxynitride, and a low-k material. A dielectric constant of the low-k material may have a value smaller than 3.9, which is a dielectric constant of silicon oxide.

The first source/drain contact 180 may be disposed on the first source/drain pattern 150. The first source/drain contact 180 is electrically connected to the first source/drain pattern 150. The first source/drain contact 180 may be disposed between the first channel separation structure CCW1 and the gate separation structure GCS.

The second source/drain contact 280 may be disposed on the second source/drain pattern 250. The second source/drain contact 280 is electrically connected to the second source/drain pattern 250. The second source/drain contact 280 may be disposed between the first channel separation structure CCW1 and the gate separation structure GCS.

The third source/drain contact 380 may be disposed on the third source/drain pattern 350. The third source/drain contact 380 is electrically connected to the third source/drain pattern 350. The fourth source/drain contact 480 may be disposed on the fourth source/drain pattern 450. The fourth source/drain contact 480 is electrically connected to the fourth source/drain pattern 450.

A first contact silicide film 155 may be disposed between the first source/drain contact 180 and the first source/drain pattern 150. A second contact silicide film 255 may be disposed between the second source/drain contact 280 and the second source/drain pattern 250. A third contact silicide film 355 may be disposed between the third source/drain contact 380 and the third source/drain pattern 350. A fourth contact silicide film 455 may be disposed between the fourth source/drain contact 480 and the fourth source/drain pattern 450.

Although it is illustrated that the first to fourth source/drain contacts 180, 280, 380, and 480 have a single conductive film structure, the present disclosure is not limited thereto. Unlike illustrated, the source/drain contacts 180, 280, 380, and 480 may have a multi-conductive film structure including a barrier film and a plug film. The first to fourth source/drain contacts 180, 280, 380, and 480 may include, for example, at least one of a metal, conductive metal nitride, conductive metal carbide, conductive metal oxide, conductive metal carbonitride, and a two-dimensional (2D) material. The first to fourth contact silicide films 155, 255, 355, and 455 may include a metal silicide material.

The 2D material may include a two-dimensional allotrope or a two-dimensional compound, and may include, for example, at least one of, for example, graphene, boron nitride (BN), molybdenum sulfide, molybdenum selenide, tungsten sulfide, tungsten selenide, and tantalum sulfide, but is not limited thereto. That is, since the above-described 2D material is only listed as an example, the 2D material that may be included in the semiconductor device of the present disclosure is not limited by the above-described material.

The alignment mark area 20 may include a first sub-alignment mark area 21 and a second sub-alignment mark area 22. A plurality of first alignment mark patterns 510 may be disposed in the first sub-alignment mark area 21. A plurality of second alignment mark patterns 610 may be disposed in the second sub-alignment mark area 22.

Each first alignment mark pattern 510 may be disposed on the first substrate 100. For example, each first alignment mark pattern 510 may be disposed on the first surface 100US of the first substrate 100. Each first alignment mark pattern 510 may include a plurality of first lower alignment insulating patterns 520 and a first upper alignment insulating pattern 525.

Each second alignment mark pattern 610 may be disposed on the first substrate 100. For example, each second alignment mark pattern 610 may be disposed on the first surface 100US of the first substrate 100. Each second alignment mark pattern 610 may include a plurality of second lower alignment insulating patterns 620 and a second upper alignment insulating pattern 625.

In the first sub-alignment mark area 21, a fifth lower pattern BP5 and a first alignment mark pattern 510 may be disposed. In the second sub-alignment mark area 22, a sixth lower pattern BP6 and a second alignment mark pattern 610 may be disposed.

The fifth lower pattern BP5 and the sixth lower pattern BP6 may be disposed on the first substrate 100. Each of the fifth lower pattern BP5 and the sixth lower pattern BP6 may protrude in the third direction DR3 from the first surface 100US of the first substrate 100.

A sidewall of the fifth lower pattern BP5 may be defined by the fin trench FT. A sidewall of the sixth lower pattern BP6 may be defined by the fin trench FT. The field insulating film 105 may be disposed on the sidewall of the fifth lower pattern BP5 and the sidewall of the sixth lower pattern BP6. The field insulating film 105 may cover the sidewall of the fifth lower pattern BP5 and the sidewall of the sixth lower pattern BP6.

The fifth lower pattern BP5 may include a plurality of first sub-fin type patterns BP5_SP. Each first sub-fin type pattern BP5_SP may extend in a fifth direction DR5. The first sub-fin type patterns BP5_SP adjacent to each other may be spaced apart from each other in a fourth direction DR4.

The sixth lower pattern BP6 may include a plurality of second sub-fin type patterns BP6_SP. Each second sub-fin type pattern BP6_SP may extend in the fourth direction DR4. The second sub-fin type patterns BP6_SP adjacent to each other may be spaced apart from each other in the fifth direction DR5.

For example, the fourth direction DR4 and the fifth direction DR5 may each be perpendicular to the third direction DR3. The fourth direction DR4 may be perpendicular to the fifth direction DR5. As an example, the fourth direction DR4 may be the same direction as the first direction DR1, and the fifth direction DR5 may be the same direction as the second direction DR2. As another example, the fourth direction DR4 may be the same direction as the second direction DR2, and the fifth direction DR5 may be the same direction as the first direction DR1.

The fifth lower pattern BP5 and the sixth lower pattern BP6 may each include silicon or germanium, which is an elemental semiconductor material. Alternatively, the fifth lower pattern BP5 and the sixth lower pattern BP6 may each include a compound semiconductor, for example, a group IV-IV compound semiconductor or a group III-V compound semiconductor.

The plurality of first lower alignment insulating patterns 520 may be disposed on the first substrate 100. The plurality of first lower alignment insulating patterns 520 may be disposed on the first surface 100US of the first substrate 100. Each first lower alignment insulating pattern 520 may extend in the fifth direction DR5. The first lower alignment insulating patterns 520 may be spaced apart from each other in the fourth direction DR4. In plan view, the first lower alignment insulating pattern 520 may have a line shape extending lengthwise in the fifth direction DR5.

Each first lower alignment insulating pattern 520 may be disposed between the first sub-fin type patterns BP5_SP adjacent to each other in the fourth direction DR4. Each first lower alignment insulating pattern 520 may extend along the first sub-fin type pattern BP5_SP.

Each first lower alignment insulating pattern 520 may be in contact with the first sub-fin type pattern BP5_SP. Each first lower alignment insulating pattern 520 may be in contact with the field insulating film 105.

The number of first sub-fin type patterns BP5_SP is greater than the number of first lower alignment insulating patterns 520. For example, the number of first sub-fin type patterns BP5_SP is one more than the number of first lower alignment insulating patterns 520.

The first upper alignment insulating pattern 525 may be disposed on the first lower alignment insulating pattern 520. The first lower alignment insulating pattern 520 may be disposed between the first upper alignment insulating pattern 525 and the first substrate 100. The first upper alignment insulating pattern 525 may be in contact with each first lower alignment insulating pattern 520. For example, the first upper alignment insulating pattern 525 may be in direct contact with each first lower alignment insulating pattern 520.

The first upper alignment insulating pattern 525 may be spaced apart from the fifth lower pattern BP5 in the third direction DR3. The first upper alignment insulating pattern 525 may be spatially separated from the fifth lower pattern BP5. The first upper alignment insulating pattern 525 is not in contact with the first sub-fin type pattern BP5_SP.

The first upper alignment insulating patterns 525 may extend in the fourth direction DR4. In plan view, the first upper alignment insulating pattern 525 may have a line shape extending lengthwise in the fourth direction DR4.

The plurality of second lower alignment insulating patterns 620 may be disposed on the first substrate 100. Each second lower alignment insulating pattern 620 may extend in the fourth direction DR4. The second lower alignment insulating patterns 620 may be spaced apart from each other in the fifth direction DR5. In plan view, the second lower alignment insulating pattern 620 may have a line shape extending lengthwise in the fourth direction DR4.

Each second lower alignment insulating pattern 620 may be disposed between the second sub-fin type patterns BP6_SP adjacent to each other in the fifth direction DR5. Each second lower alignment insulating pattern 620 may extend along the second sub-fin type pattern BP6_SP. For example, the number of second sub-fin type patterns BP6_SP is one more than the number of second lower alignment insulating patterns 620.

Each second lower alignment insulating pattern 620 may be in contact with the second sub-fin type pattern BP6_SP. Although not illustrated, each second lower alignment insulating pattern 560 may be in contact with the field insulating film 105. Although not illustrated, a cross-sectional view of the second alignment mark pattern 610 cut in the fourth direction DR4 may be substantially the same as FIG. 13.

The second upper alignment insulating pattern 625 may be disposed on the second lower alignment insulating pattern 620. The second lower alignment insulating pattern 620 may be disposed between the second upper alignment insulating pattern 625 and the first substrate 100. The second upper alignment insulating pattern 625 may be in contact with each second lower alignment insulating pattern 620. For example, the second upper alignment insulating pattern 625 may be in direct contact with each second lower alignment insulating pattern 620.

The second upper alignment insulating pattern 625 may be spaced apart from the sixth lower pattern BP6 in the third direction DR3. The second upper alignment insulating pattern 625 is not in contact with the second sub-fin type pattern BP6_SP.

The second upper alignment insulating patterns 625 may extend in the fifth direction DR5. In plan view, the second upper alignment insulating pattern 625 may have a line shape extending lengthwise in the fifth direction DR5.

A width W31 of the first lower alignment insulating pattern 520 in the fifth direction DR5 is greater than a width W32 of the first upper alignment insulating pattern 525 in the fifth direction DR5. A width of the first sub-fin type pattern BP5_SP in the fifth direction DR5 is greater than the width W32 of the first upper alignment insulating pattern 525 in the fifth direction DR5. A width of the second lower alignment insulating pattern 620 in the fourth direction DR4 is greater than a width of the second upper alignment insulating pattern 625 in the fourth direction DR4.

While the first channel separation structure CCW1 and the second channel separation structure CCW2 are formed, the first alignment mark pattern 510 and the second alignment mark pattern 610 may be formed. The first alignment mark pattern 510 and the second alignment mark pattern 610 may include the same material as the first channel separation structure CCW1 and the second channel separation structure CCW2.

The first lower alignment insulating pattern 520 and the second lower alignment insulating pattern 620 include an insulating material. The first upper alignment insulating pattern 525 and the second upper alignment insulating pattern 625 include an insulating material. When the first lower alignment insulating pattern 520 and the first upper alignment insulating pattern 525 include the same insulating material, a boundary between the first lower alignment insulating pattern 520 and the first upper alignment insulating pattern 525 may not be distinguished.

In FIGS. 7 and 12, the height H15 from the bottom surface 105BS of the field insulating film 105 to the uppermost portion of the first portion CCW1_R21 of the second area of the first channel separation structure may be equal to a height H23 from the bottom surface 105BS of the field insulating film 105 to the uppermost portion of the first lower alignment insulating pattern 520. When the boundary between the first lower alignment insulating pattern 520 and the first upper alignment insulating pattern 525 is not distinguished, the height H15 from the bottom surface 105BS of the field insulating film 105 to the uppermost portion of the first portion CCW1_R21 of the second area of the first channel separation structure may be greater than the height H23 from the bottom surface 105BS of the field insulating film 105 to the uppermost portion of the first lower alignment insulating pattern 520.

The first upper alignment insulating pattern 525 may include an upper surface 525US and a bottom surface 525BS that are opposite to each other in the third direction DR3. The bottom surface 525BS of the first upper alignment insulating pattern may face the first sub-fin type pattern BP5_SP. A depth H22 from the bottom surface 525BS of the first upper alignment insulating pattern to the lowest portion of the first lower alignment insulating pattern 520 may be equal to or greater than a depth H21 from the bottom surface 525BS of the first upper alignment insulating pattern to the lowest portion of the first sub-fin type pattern BP5_SP. Here, the lowermost portion of the first sub-fin type pattern BP5_SP may be positioned at the same level as the bottom surface of the fin trench FT.

The source/drain etch stop film 185 may extend along the upper surface of the first sub-fin type pattern BP5_SP, the sidewall of the first lower alignment insulating pattern 520, the bottom surface 525BS of the first upper alignment insulating pattern, and the sidewall of the first upper alignment insulating pattern 525. The source/drain etch stop film 185 may extend along the upper surface of the second sub-fin type pattern BP6_SP, the sidewall of the second lower alignment insulating pattern 620, the bottom surface of the second upper alignment insulating pattern 625, and the sidewall of the second upper alignment insulating pattern 625.

The upper interlayer insulating film 190 may fill a space between the first sub-fin type pattern BP5_SP and the first upper alignment insulating pattern 525. The upper interlayer insulating film 190 may fill a space between the second sub-fin type pattern BP6_SP and the second upper alignment insulating pattern 625.

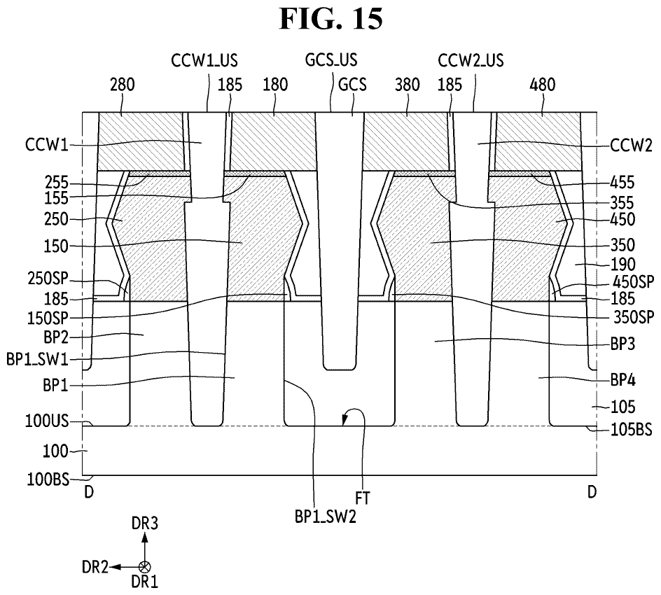

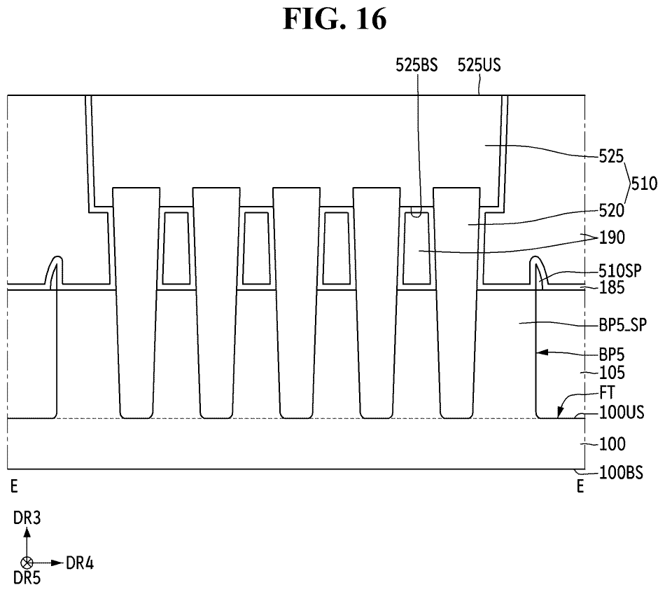

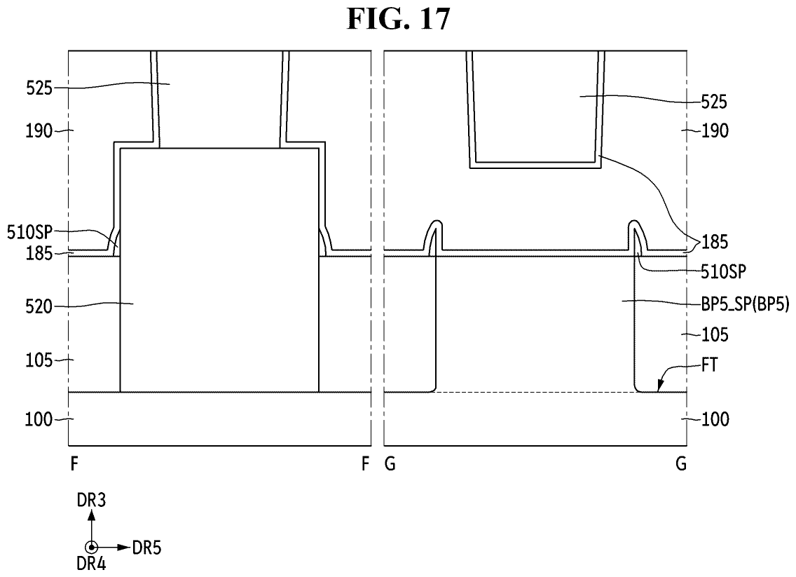

FIGS. 15 to 17 are views for describing a semiconductor device according to some example embodiments. For convenience of explanation, points different from those described with reference to FIGS. 1 to 14 will be mainly described.

Referring to FIGS. 15 to 17, the semiconductor device according to some example embodiments may further include first to fourth source/drain fences 150SP, 250SP, 350SP, and 450SP and first and second alignment pattern spacers 510SP and 610SP disposed on the upper surface 105US of the field insulating film 105.

The first to fourth source/drain fences 150SP, 250SP, 350SP, and 450SP may each protrude in the third direction DR3 from the upper surface 105US of the field insulating film 105. The first to fourth source/drain fences 150SP, 250SP, 350SP, and 450SP may be in contact with the first to fourth source/drain patterns 150, 250, 350, and 450, respectively.

The first source/drain fence 150SP may be disposed on a portion of the first source/drain pattern 150. The second source/drain fence 250SP may be disposed on a portion of the second source/drain pattern 250. The third source/drain fence 350SP may be disposed on a portion of the third source/drain pattern 350. The fourth source/drain fence 450SP may be disposed on a portion of the fourth source/drain pattern 450.

The first and second alignment pattern spacers 510SP and 610SP may each protrude in the third direction DR3 from the upper surface 105US of the field insulating film 105. The first alignment pattern spacer 510SP may be disposed along a circumference of the fifth lower pattern BP5. The second alignment pattern spacer 610SP may be disposed along a circumference of the sixth lower pattern BP6.

Although it is illustrated that the uppermost portion of the first alignment pattern spacer 510SP is lower than the bottom surface 525BS of the first upper alignment insulating pattern based on the first surface 100US of the first substrate 100, this is merely for convenience of explanation and the present disclosure is not limited.

The first to fourth source/drain fences 150SP, 250SP, 350SP, and 450SP and the first and second alignment pattern spacers 510SP and 610SP may include the materials included in the first gate spacer 140 and the third gate spacer 340. For example, during the manufacturing process, the first to fourth source/drain fences 150SP, 250SP, 350SP, and 450SP and the first and second alignment pattern spacers 510SP and 610SP may be formed together with the first gate spacer 140 and the third gate spacer 340.

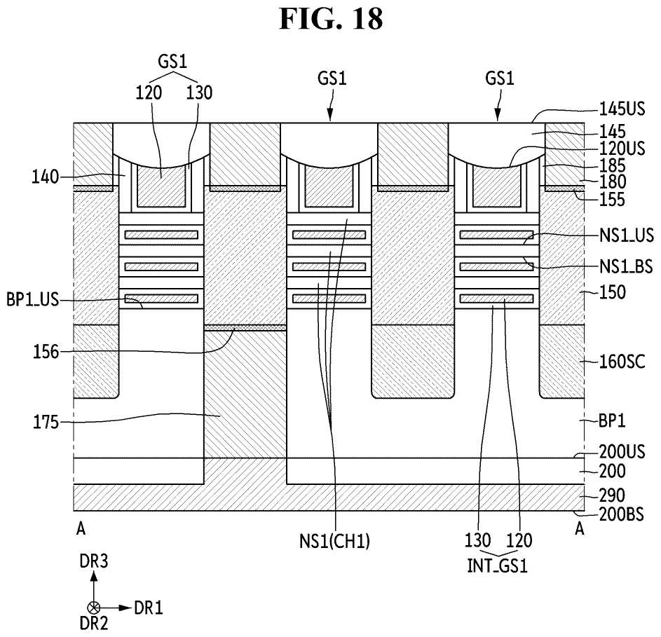

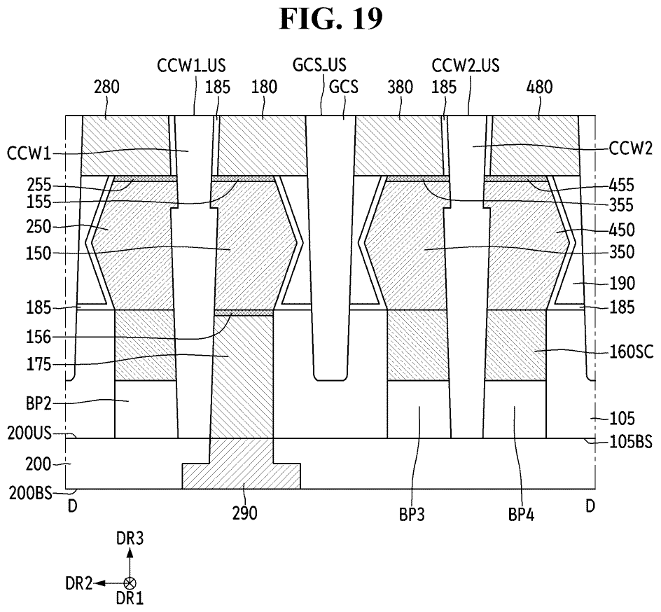

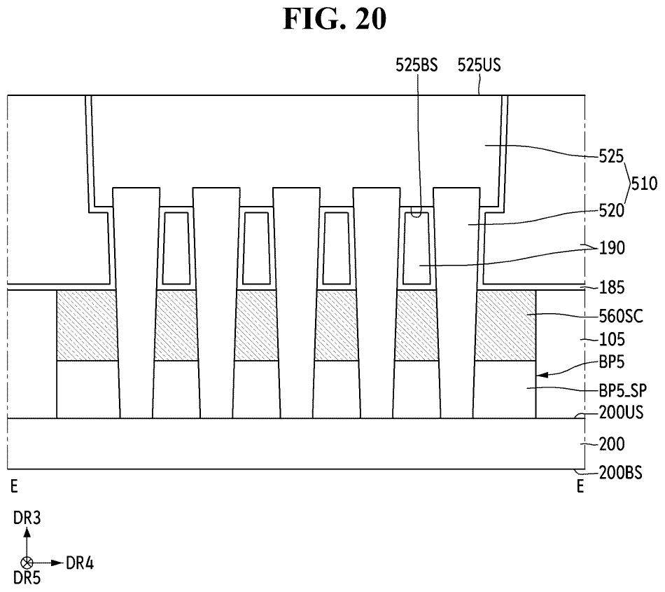

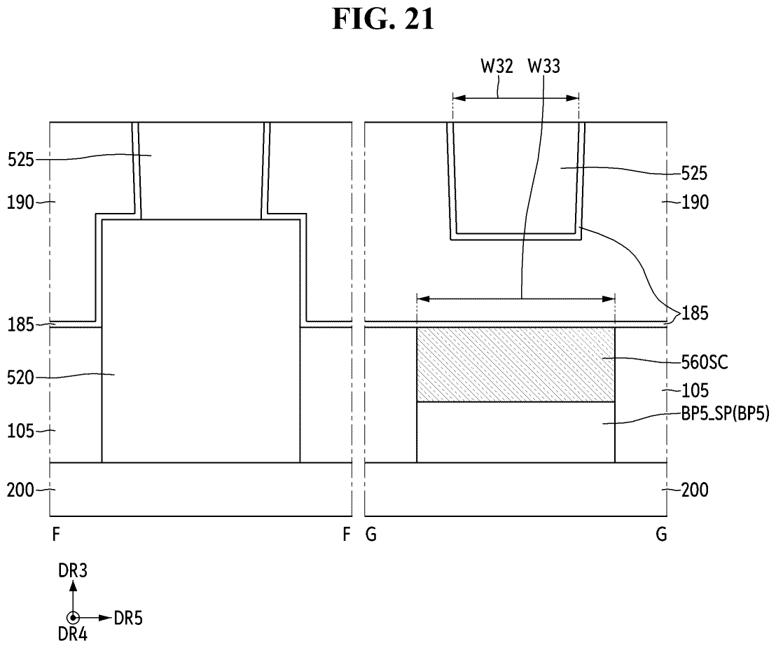

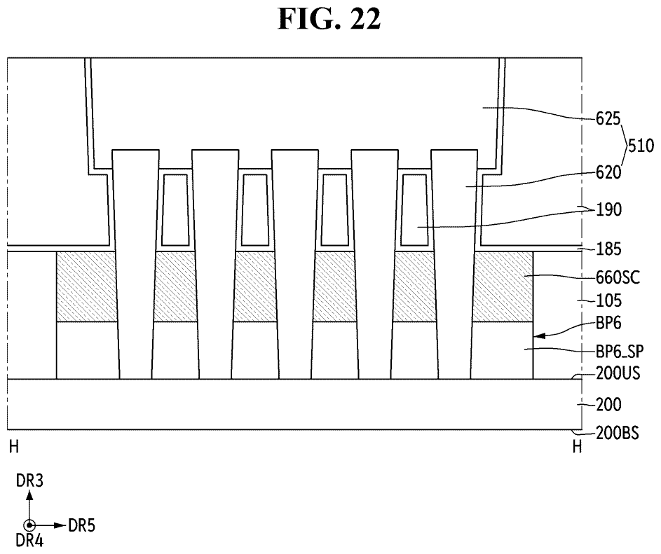

FIGS. 18 to 22 are views for describing a semiconductor device according to some example embodiments. For convenience of explanation, points different from those described with reference to FIGS. 1 to 14 will be mainly described.

Referring to FIGS. 18 to 22, a semiconductor device according to some example embodiments may further include a sacrificial semiconductor pattern 160SC, a first alignment semiconductor pattern 560SC, a second alignment semiconductor pattern 660SC, a backside source/drain contact 175, and a backside wiring line 290.

The first lower pattern BP1, the second lower pattern BP2, the third lower pattern BP3, and the fourth lower pattern BP4 may be disposed on a second substrate 200. The second substrate 200 may include a first surface 200US and a second surface 200BS that are opposite to each other in the third direction DR3. The first to fourth lower patterns BP1, BP2, BP3, and BP4 are disposed on the first surface 200US of the second substrate.

The second substrate 200 may include an insulating material and may include at least one of silicon oxide, silicon nitride, and a combination thereof. The second substrate 200 may be a substrate formed by a deposition process or the like after the first substrate 100 of FIGS. 4 to 7 and 12 to 14 is removed during the manufacturing process. For example, the second substrate 200 may be a base film on which the logic cell area 10 and the alignment mark area 20 are disposed.

The field insulating film 105 may be in contact with the second substrate 200. The bottom surface 105BS of the field insulating film 105 faces the second substrate 200.

The sacrificial semiconductor pattern 160SC may be disposed on the second substrate 200. The sacrificial semiconductor pattern 160SC may be disposed within the first to fourth lower patterns BP1, BP2, BP3, and BP4. The sacrificial semiconductor pattern 160SC may be disposed between the first to fourth source/drain patterns 150, 250, 350, and 450 and the second substrate 200. The sacrificial semiconductor pattern 160SC may overlap the first to fourth source/drain patterns 150, 250, 350, and 450 in the third direction DR3.

The sacrificial semiconductor pattern 160SC may include a material having an etching selectivity with respect to the first to fourth lower patterns BP1, BP2, BP3, and BP4. When the first to fourth lower patterns BP1, BP2, BP3, and BP4 are silicon patterns, the sacrificial semiconductor pattern 160SC may include silicon germanium.

The backside wiring line 290 may be disposed within the second substrate 200. The backside wiring line 290 may include a line portion and a via portion. Although it is illustrated that the line portion of the backside wiring line 290 extends in the first direction DR1, this is merely for convenience of explanation and the present disclosure is not limited thereto. The via portion of the backside wiring line 290 may protrude in the third direction DR3 from the line portion of the backside wiring line 290. Unlike illustrated, the backside wiring line 290 may not include the via portion.

The backside source/drain contact 175 may be disposed between the first source/drain pattern 150 and the backside wiring line 290. The backside source/drain contact 175 electrically connects the first source/drain pattern 150 and the backside wiring line 290.

It is illustrated that each of the backside source/drain contact 175 is connected to a portion of the first source/drain pattern 150, but this is merely for convenience of explanation and the present disclosure is not limited thereto. Unlike illustrated, the backside source/drain contact 175 may be connected to the second to fourth source/drain patterns 250, 350, and 450.

A backside contact silicide film 156 may be disposed between the backside source/drain contact 175 and the first source/drain pattern 150.

The backside source/drain contact 175 and the backside wiring line 290 are each illustrated as being a single conductive film, but are not limited thereto. Unlike illustrated, at least one of the backside source/drain contact 175 and the backside wiring line 290 may have a multi-conductive film structure including a barrier film and a filling film. The backside source/drain contact 175 and the backside wiring line 290 may each include, for example, at least one of a metal, conductive metal nitride, conductive metal carbide, conductive metal oxide, conductive metal carbonitride, and a two-dimensional material.

The first alignment semiconductor pattern 560SC and the second alignment semiconductor pattern 660SC may be disposed on the second substrate 200.

The first alignment semiconductor pattern 560SC may be disposed on the fifth lower pattern BP5. The first alignment semiconductor pattern 560SC may be disposed on each first sub-fin type pattern BP5_SP. The first alignment semiconductor pattern 560SC may be disposed between the first lower alignment insulating patterns 520 adjacent to each other in the fourth direction DR4. The first alignment semiconductor pattern 560SC may be in contact with the first lower alignment insulating pattern 520.

The first alignment semiconductor pattern 560SC may be spaced apart from the first upper alignment insulating pattern 525 in the third direction DR3. The first alignment semiconductor pattern 560SC may not be in contact with the first upper alignment insulating pattern 525. For example, the first alignment semiconductor pattern 560SC may not be in contact with the bottom surface 525BS of the first upper alignment insulating pattern.

Each first alignment semiconductor pattern 560SC may extend in the fifth direction DR5. In plan view, the first alignment semiconductor pattern 560SC may have a line shape extending lengthwise in the fifth direction DR5. Each first alignment semiconductor pattern 560SC may be in contact with the field insulating film 105.

The second alignment semiconductor pattern 660SC may be disposed on the sixth lower pattern BP6. The second alignment semiconductor pattern 660SC may be disposed on each second sub-fin type pattern BP6_SP. The second alignment semiconductor pattern 660SC may be disposed between the second lower alignment insulating patterns 620 adjacent to each other in the fifth direction DR5. The second alignment semiconductor pattern 660SC may be in contact with the second lower alignment insulating pattern 620.

The second alignment semiconductor pattern 660SC may be spaced apart from the second upper alignment insulating pattern 625 in the third direction DR3. The second alignment semiconductor pattern 660SC may not be in contact with the second upper alignment insulating pattern 625.

Each second alignment semiconductor pattern 660SC may extend in the fourth direction DR4. In plan view, the second alignment semiconductor pattern 660SC may have a line shape extending lengthwise in the fourth direction DR4. Although not illustrated, each second alignment semiconductor pattern 660SC may be in contact with the field insulating film 105.

A width W33 of the first alignment semiconductor pattern 560SC in the fifth direction DR5 is greater than the width W32 of the first upper alignment insulating pattern 525 in the fifth direction DR5. A width of the second alignment semiconductor pattern 660SC in the fourth direction DR4 is greater than the width of the second upper alignment insulating pattern 625 in the fourth direction DR4.

The first alignment semiconductor pattern 560SC includes the same material as the second alignment semiconductor pattern 660SC. In the manufacturing process, the first alignment semiconductor pattern 560SC and the second alignment semiconductor pattern 660SC may be formed together with the sacrificial semiconductor pattern 160SC. The sacrificial semiconductor pattern 160SC includes the same material as the first alignment semiconductor pattern 560SC and the second alignment semiconductor pattern 660SC.

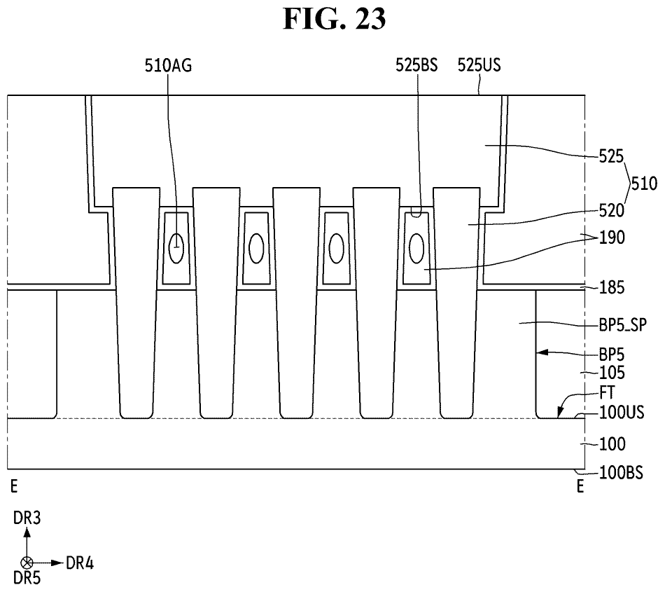

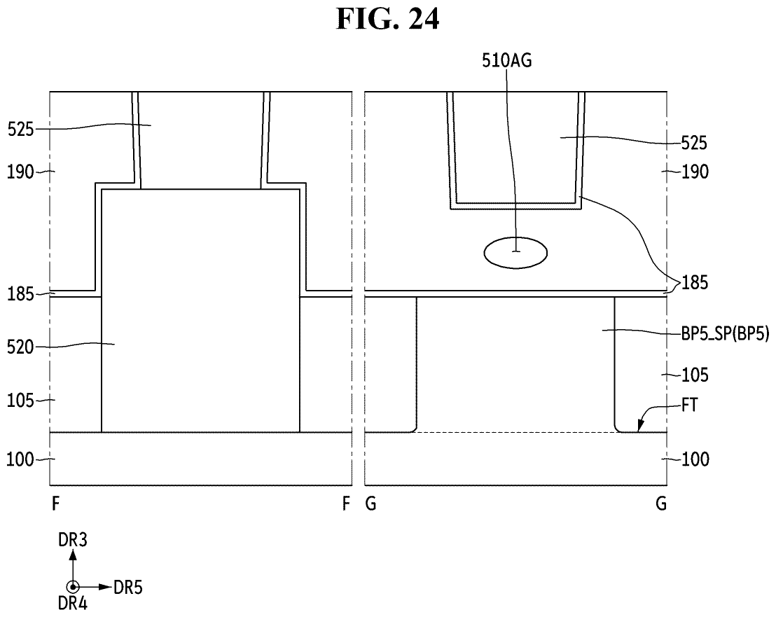

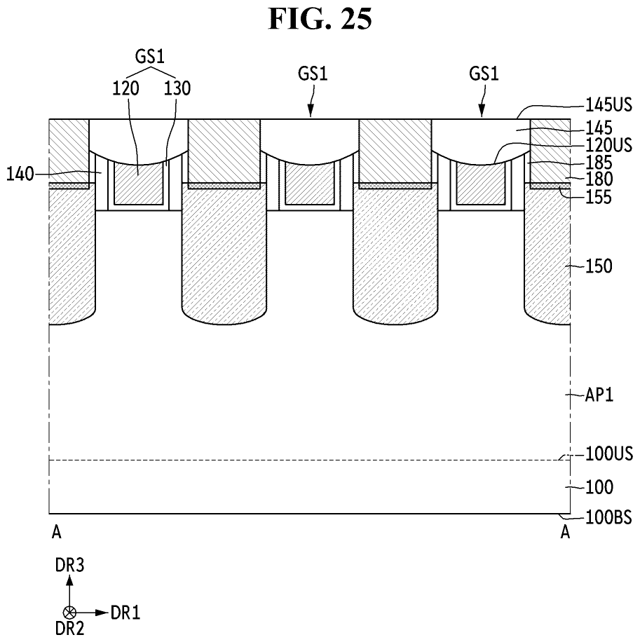

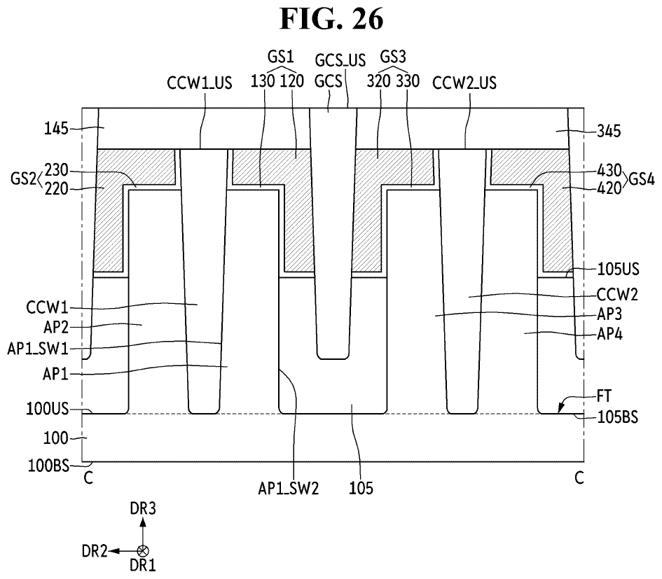

FIGS. 23 and 24 are views for describing a semiconductor device according to some example embodiments. FIGS. 25 and 26 are views for describing a semiconductor device according to some example embodiments. For convenience of explanation, points different from those described with reference to FIGS. 1 to 14 will be mainly described.

Referring to FIGS. 23 and 24, a semiconductor device according to some example embodiments may further include an alignment air gap 510AG disposed between the first sub-fin type pattern BP5_SP and the first upper alignment insulating pattern 525

The alignment air gap 510AG may be surrounded by the upper interlayer insulating film 190. The alignment air gap 510AG may be disposed between the first lower alignment insulating patterns 520 adjacent to each other in the fourth direction DR4. The alignment air gap 510AG may overlap the first upper alignment insulating pattern 525 in the third direction DR3.

Although not illustrated, the alignment air gap may be disposed between the second sub-fin type pattern BP6_SP and the second upper alignment insulating pattern 625.

Referring to FIGS. 25 and 26, in the semiconductor device according to some example embodiments, the first to fourth active patterns AP1, AP2, AP3, and AP4 may not include the first to fourth channel patterns CH1, CH2, CH3, and CH4 that include the first to fourth sheet patterns NS1, NS2, NS3, and NS4.

Parts of the first to fourth active patterns AP1, AP2, AP3, and AP4 may be used as a channel region of the transistor. The first active pattern AP1 will be described as an example. The first active pattern AP1 may include a first sidewall AP1_SW1 and a second sidewall AP1_SW2 that are opposite to each other in the second direction DR2. The first sidewall AP1_SW1 of the first active pattern may be in contact with the first channel separation structure CCW1. The field insulating film 105 may cover a portion of the second sidewall AP1_SW2 of the first active pattern. The first gate insulating film 130 may extend along the remainder of the second sidewall AP1_SW2 of the first active pattern.

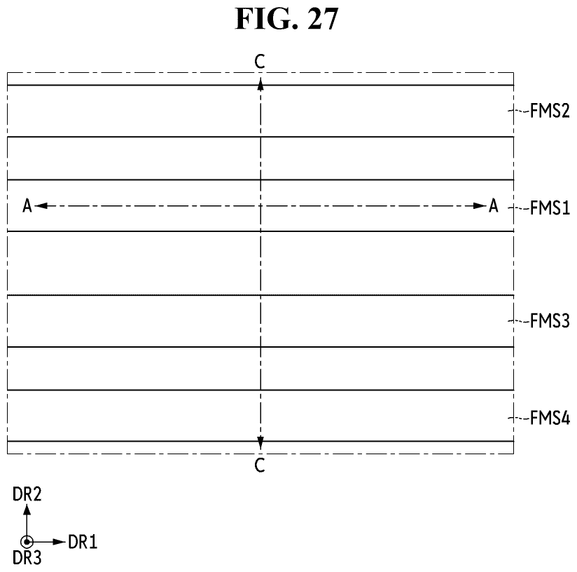

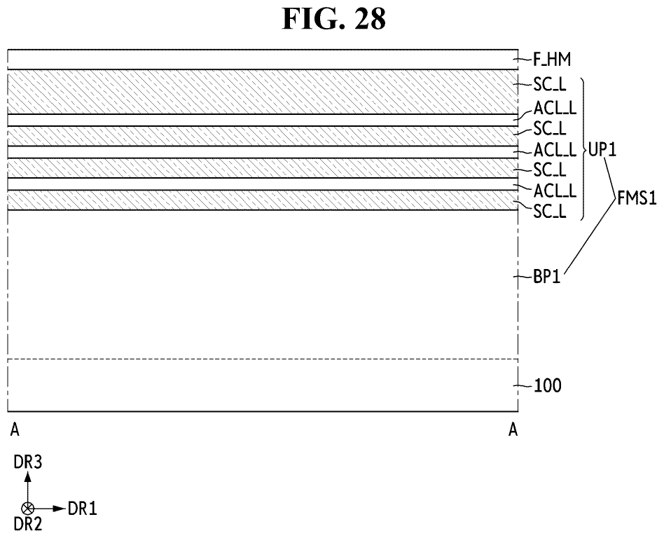

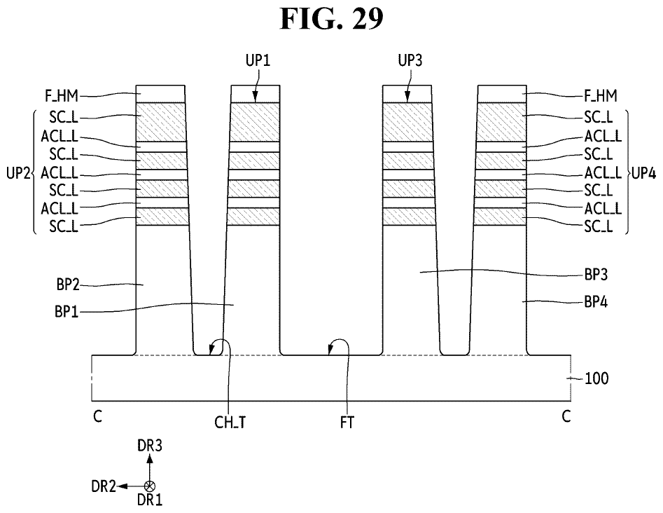

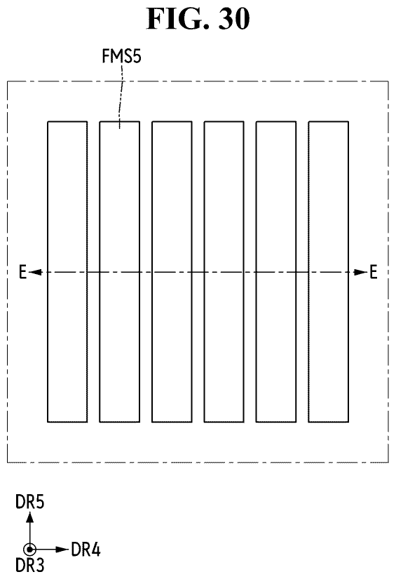

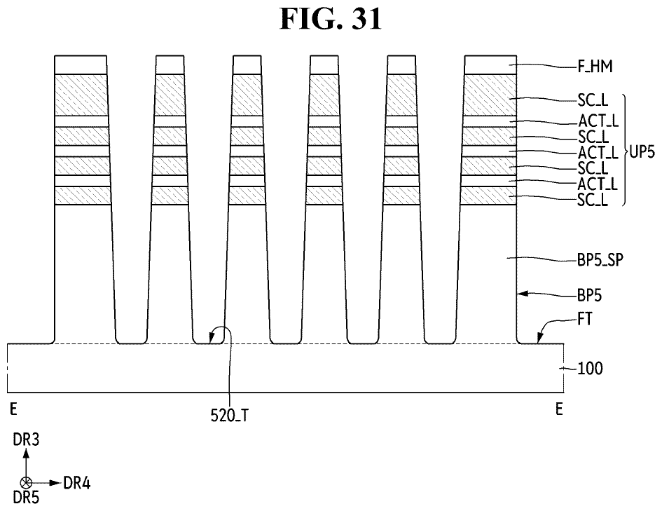

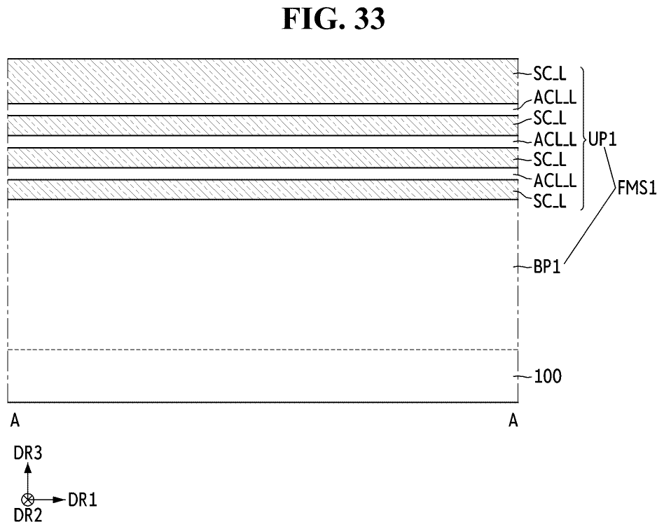

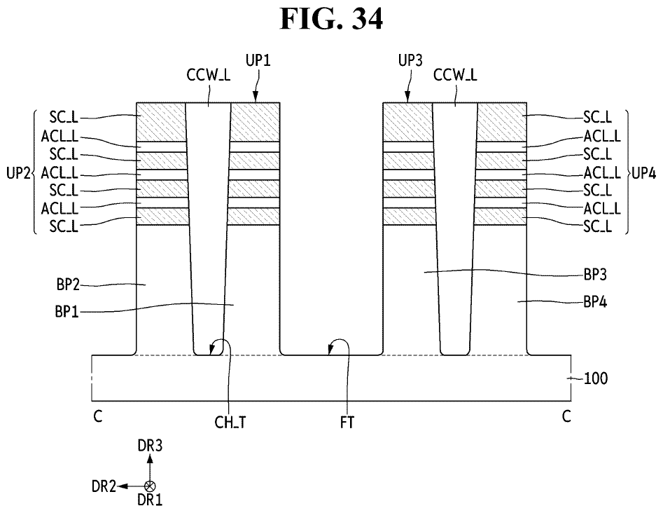

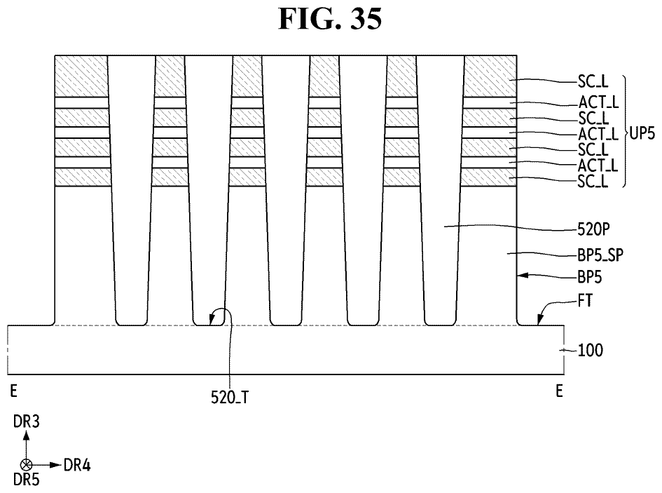

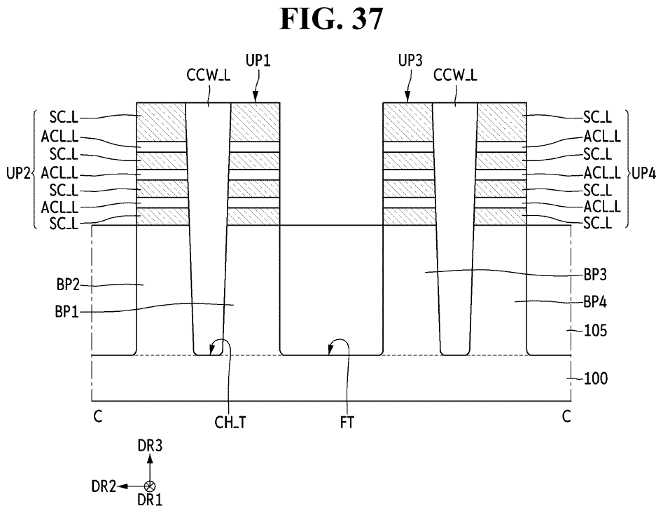

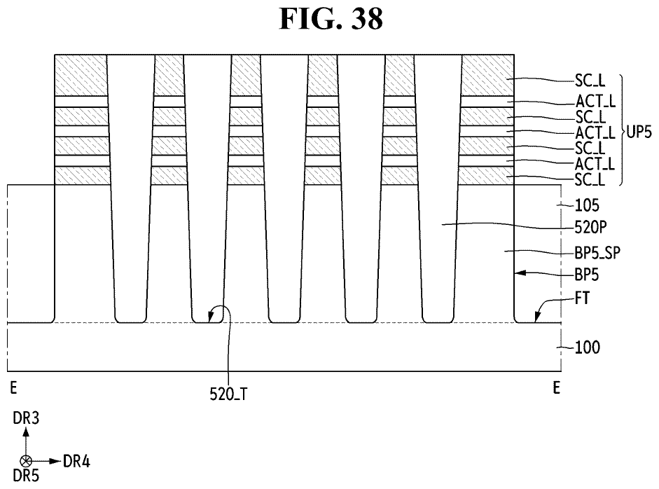

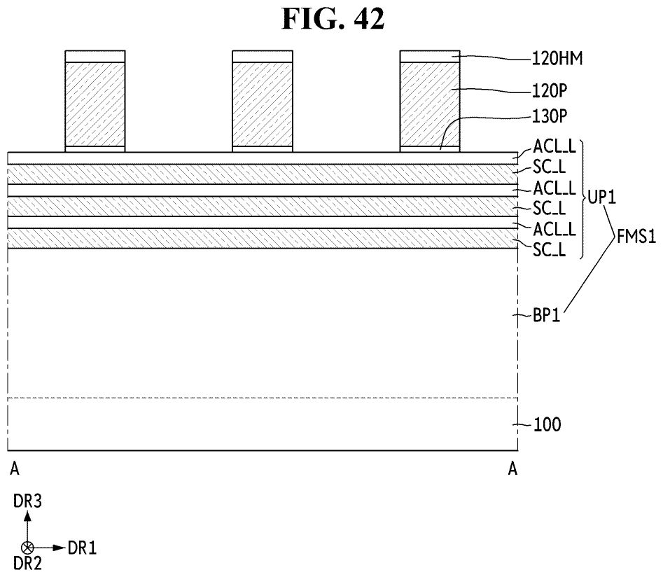

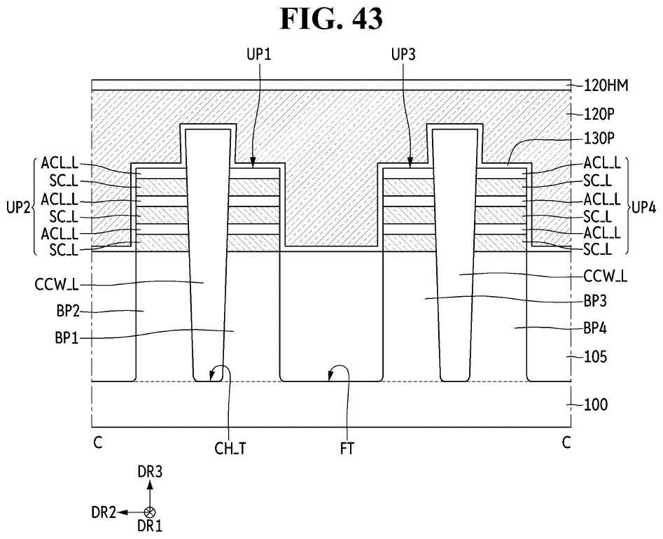

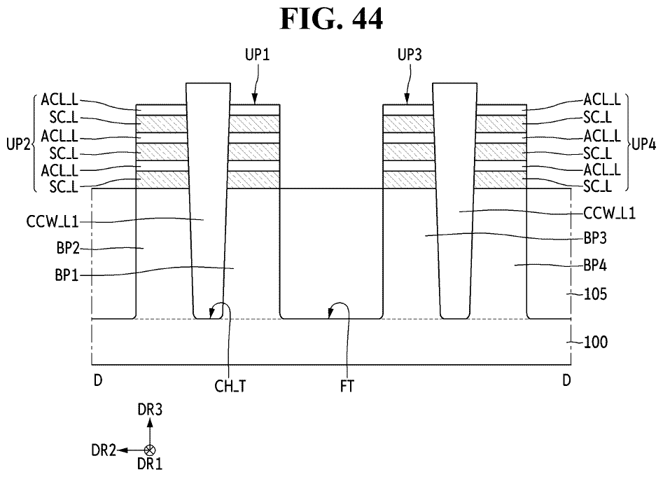

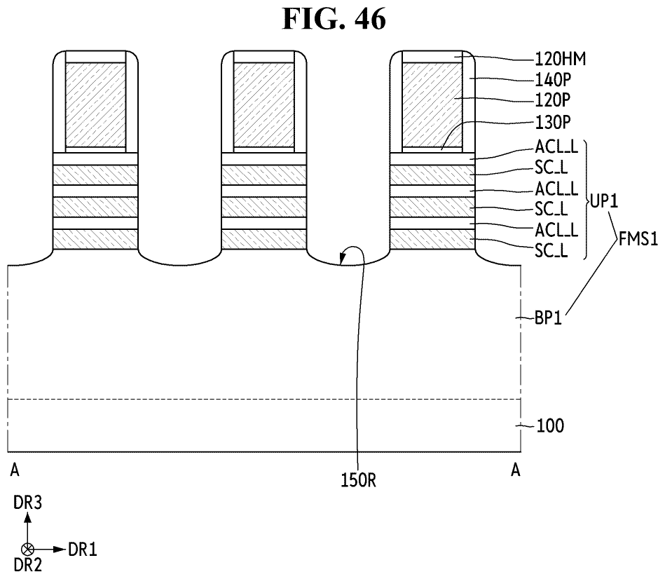

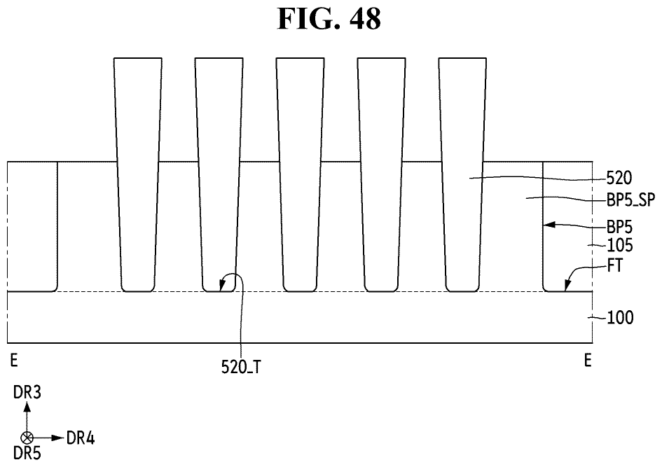

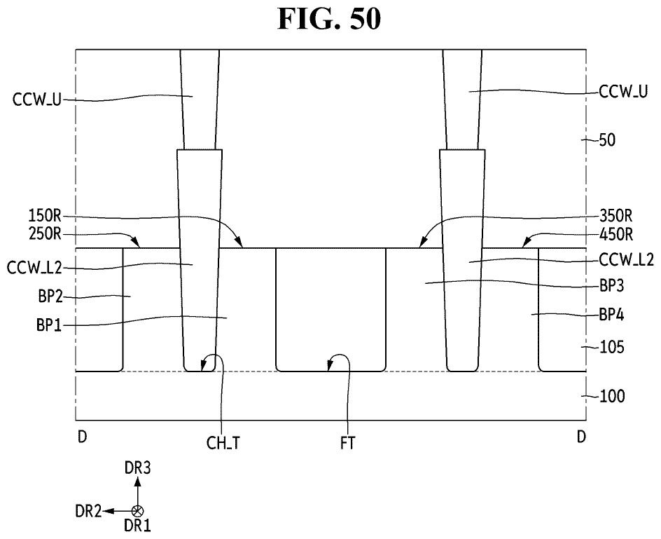

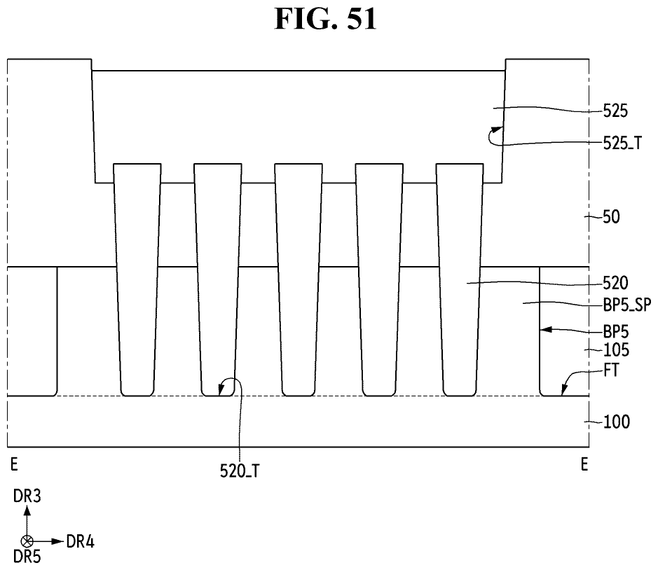

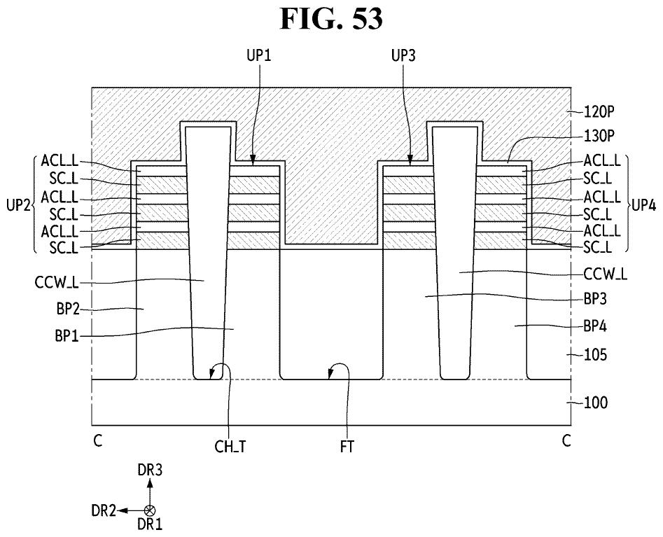

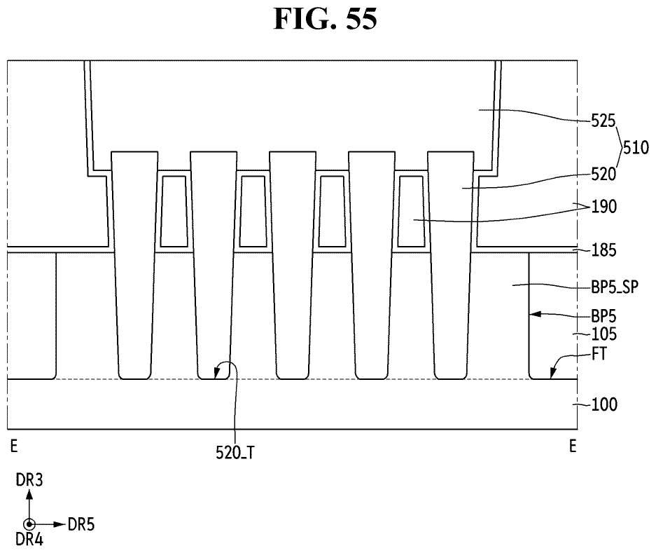

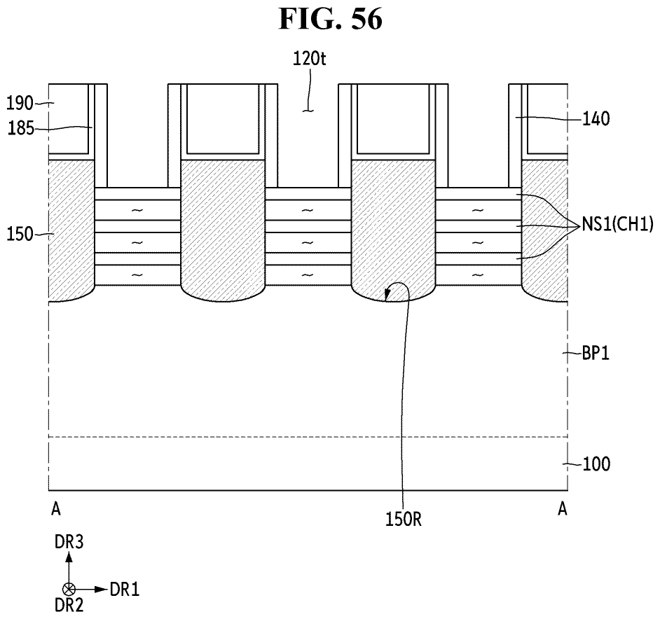

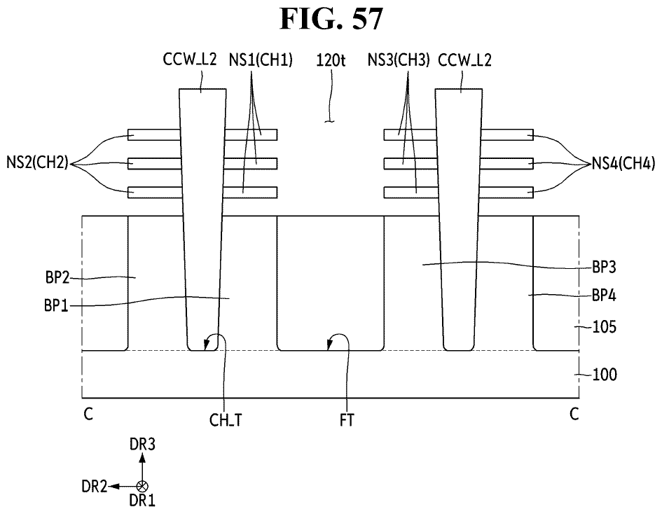

FIGS. 27 to 59 are intermediate step views for describing a method for manufacturing a semiconductor device according to some example embodiments.

Referring to FIGS. 27 to 31, on the first substrate 100, first to fourth mold fin type patterns FMS1, FMS2, FMS3, and FMS4 and a plurality of fifth mold fin type patterns FMS5 may be formed.

The first to fourth mold fin type patterns FMS1, FMS2, FMS3, and FMS4 may each extend in the first direction DR1. The first to fourth mold fin type patterns FMS1, FMS2, FMS3, and FMS4 may be spaced apart from each other in the second direction DR2.

The first mold fin type pattern FMS1 and the second mold fin type pattern FMS2 may be separated by a channel trench CH_T extending in the first direction DR1. The third mold fin type pattern FMS3 and the fourth mold fin type pattern FMS4 may be separated by a channel trench CH_T extending in the first direction DR1. The first mold fin type pattern FMS1 and the third mold fin type pattern FMS3 may be separated by a channel trench CH_T extending in the first direction DR1.

Two mold fin type patterns may be formed between the fin trenches FT adjacent to each other in the second direction DR2. The two mold fin type patterns formed between the fin trenches FT may be separated by the channel trench CH_T. A bottom surface of the channel trench CH_T is illustrated as being positioned at the same height level as the bottom surface of the fin trench FT, but is not limited thereto. Unlike illustrated, the bottom surface of the channel trench CH_T may be positioned lower than the bottom surface of the fin trench FT.

The first mold fin type pattern FMS1 may include a first lower pattern BP1 and a first upper pattern structure UP1. The second mold fin type pattern FMS2 may include a second lower pattern BP2 and a second upper pattern structure UP2. The third mold fin type pattern FMS3 may include a third lower pattern BP3 and a third upper pattern structure UP3. The fourth mold fin type pattern FMS4 may include a fourth lower pattern BP4 and a fourth upper pattern structure UP4. The first to fourth upper pattern structures UP1, UP2, UP3, and UP4 are formed on the first to fourth lower patterns BP1, BP2, BP3, and BP4.

Each fifth mold fin type pattern FMS5 may extend in the fifth direction DR5. The fifth mold fin type patterns FMS5 may be spaced apart from each other in the fourth direction DR4. The fifth mold fin type patterns FMS5 may be separated by an alignment pattern trench 520_T.

Each fifth mold fin type pattern FMS5 may include a first sub-fin type pattern BP5_SP and a fifth upper pattern structure UP5. The fifth upper pattern structure UP5 is formed on the first sub-fin type pattern BP5_SP. Since the fifth lower pattern BP5 includes a plurality of first sub-fin type patterns BP5_SP, a plurality of fifth upper pattern structures UP5 may be disposed on one fifth lower pattern BP5.

The first to fifth upper pattern structures UP1, UP2, UP3, UP4, and UP5 may each include a plurality of sacrificial patterns SC_L and a plurality of active patterns ACT_L that are alternately stacked. For example, the active pattern ACT_L may include a silicon film. The sacrificial pattern SC_L may include a silicon-germanium film.

In the first to fifth upper pattern structures UP1, UP2, UP3, UP4, and UP5, the sacrificial pattern SC_L may be disposed at the uppermost portion. For example, the sacrificial pattern SC_L disposed at the uppermost portion may be the uppermost sacrificial pattern. A thickness of the uppermost sacrificial pattern SC_L may be greater than thicknesses of other sacrificial patterns SC_L.

A mold hard mask pattern F_HM may be disposed on each of the first to fifth mold fin type patterns FMS1, FMS2, FMS3, FMS4, and FMS5. The mold hard mask pattern F_HM may be used as a mask for forming the first to fifth mold fin type patterns FMS1, FMS2, FMS3, FMS4, and FMS5. For example, the mold hard mask pattern F_HM may include silicon nitride, but is not limited thereto.

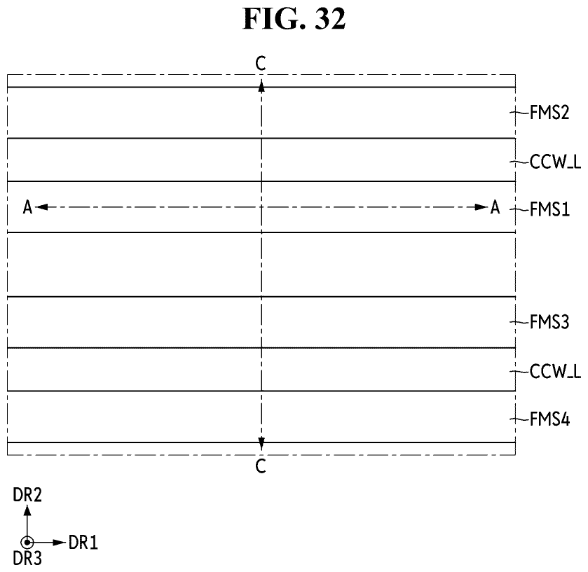

Referring to FIGS. 32 to 35, a lower channel separation structure CCW_L and a pre-lower alignment insulating pattern 520P are formed on the first substrate 100.

The lower channel separation structure CCW_L is formed within the channel trench CH_T. The lower channel separation structure CCW_L may fill the channel trench CH_T.

The pre-lower alignment insulating pattern 520P is formed within the alignment pattern trench 520_T. The pre-lower alignment insulating pattern 520P may fill the alignment pattern trench 520_T.

While the lower channel separation structure CCW_L and the pre-lower alignment insulating pattern 520P are formed, the mold hard mask pattern F_HM may be removed. Upper surfaces of the first to fifth upper pattern structures UP1, UP2, UP3, UP4, and UP5 may be exposed. For example, an upper surface of the lower channel separation structure CCW_L may be on the same plane as upper surfaces of the first to fourth mold fin type patterns FMS1, FMS2, FMS3, and FMS4. An upper surface of the pre-lower alignment insulating pattern 520P may be on the same plane as an upper surface of the fifth mold fin type pattern FMS5.

As the lower channel separation structure CCW_L is formed within the channel trench CH_T, a variation in the width of the first to fourth sheet patterns NS1, NS2, NS3, and NS4 formed by the first to fourth upper pattern structures UP1, UP2, UP3, and UP4 may be minimized.

In addition, since the lower channel separation structure CCW_L does not protrude further than the first to fourth mold fin type patterns FMS1, FMS2, FMS3, and FMS4, constraints on the subsequent manufacturing processes may be reduced.

The first area CCW1_R1 of the first channel separation structure of FIG. 6 and the first portion CCW1_R21 of the second area of the first channel separation structure of FIG. 11 may be formed by the lower channel separation structure CCW_L.

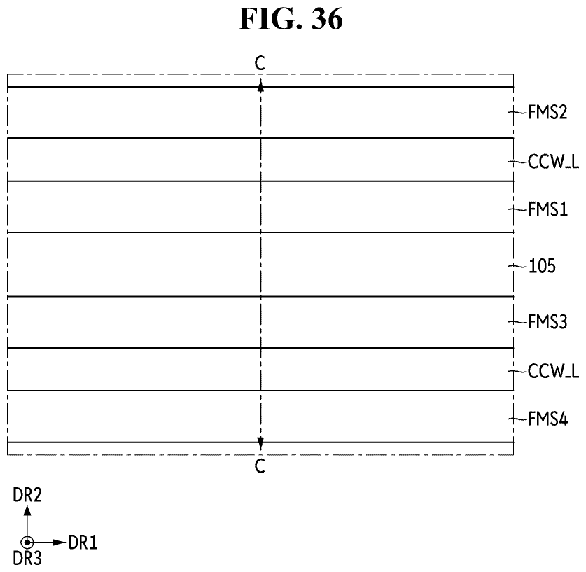

Referring to FIGS. 36 to 38, the field insulating film 105 may be formed on the first substrate 100.

The field insulating film 105 may fill a portion of the fin trench FT.

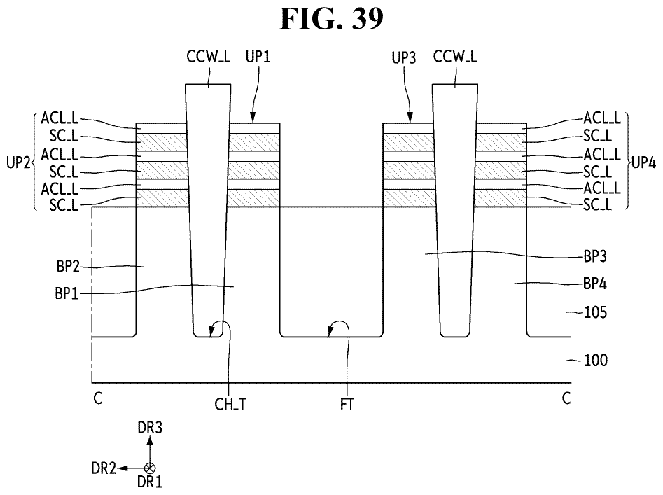

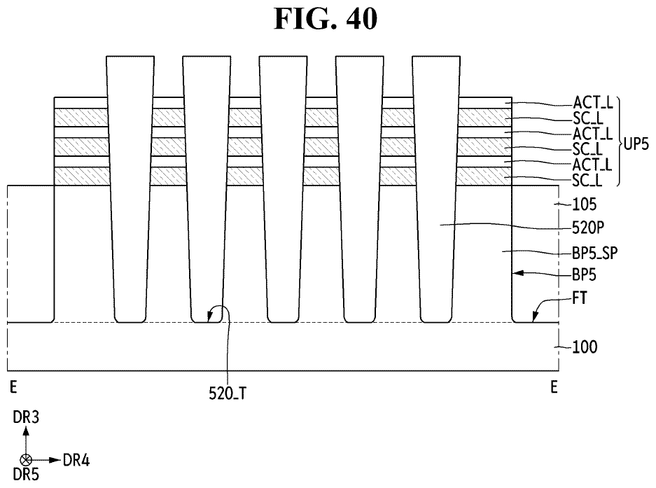

Referring to FIGS. 39 and 40, in the first to fifth upper pattern structures UP1, UP2, UP3, UP4, and UP5, the pattern SC_L disposed at the uppermost portion may be removed.

A portion of the lower channel separation structure CCW_L may protrude further in the third direction DR3 than the first to fourth upper pattern structures UP1, UP2, UP3, and UP4. A portion of the pre-lower alignment insulating pattern 520P may protrude further in the third direction DR3 than the fifth upper pattern structure UP5.

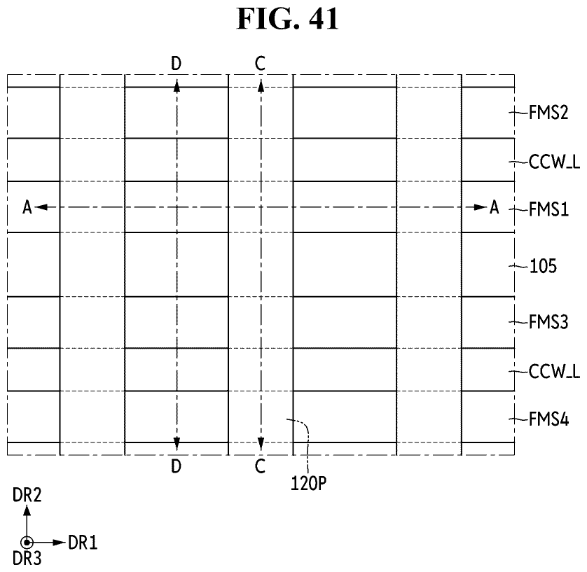

Referring to FIGS. 41 to 44, a plurality of dummy gate electrodes 120P may be formed on the first to fourth mold fin type patterns FMS1, FMS2, FMS3, and FMS4.

The plurality of dummy gate electrodes 120P may be formed on the lower channel separation structure CCW_L. Each dummy gate electrode 120P may extend in the second direction DR2. The dummy gate electrodes 120P may be spaced apart from each other in the first direction DR1.

Each dummy gate electrode 120P may intersect the first to fourth mold fin type patterns FMS1, FMS2, FMS3, and FMS4. Each dummy gate electrode 120P may intersect the lower channel separation structure CCW_L.

More specifically, a dummy gate insulating film 130P may be formed on the first to fourth mold fin type patterns FMS1, FMS2, FMS3, and FMS4. The dummy gate insulating film 130P may be formed along a profile of the first to fourth mold fin type patterns FMS1, FMS2, FMS3, and FMS4 that protrude further than the field insulating film 105. The dummy gate insulating film 130P may be formed along a profile of the lower channel separation structure CCW_L that protrudes further than the first to fourth upper pattern structures UP1, UP2, UP3, and UP4.

The dummy gate electrode 120P may be formed on the dummy gate insulating film 130P. The dummy gate electrode 120P and the dummy gate insulating film 130P may be formed using a dummy gate capping film 120HM as a mask. While the dummy gate electrode 120P and the dummy gate insulating film 130P are formed, a portion of the lower channel separation structure CCW_L that does not overlap the dummy gate electrode 120P in the third direction DR3 may be etched to form the first lower channel separation structure CCW_L1.

The dummy gate electrode 120P may include, for example, polysilicon, but is not limited thereto. The dummy gate insulating film 130P may include, for example, silicon oxide, but is not limited thereto. The dummy gate capping film 120HM may include, for example, silicon nitride, but is not limited thereto.

While the dummy gate electrode 120P is formed, a mask pattern may be formed on the alignment mark area (20 in FIG. 1). That is, the dummy gate electrode 120P may not be formed in the alignment mark area (20 in FIG. 1). After the dummy gate electrode 120P is formed, the mask pattern on the alignment mark area (20 in FIG. 1) may be removed.

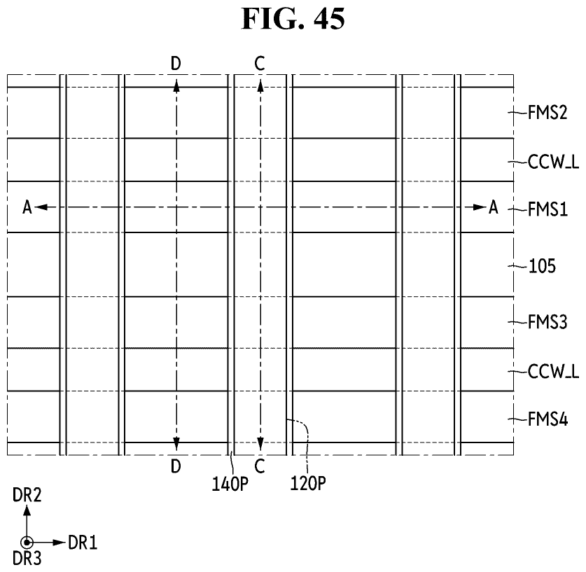

Referring to FIGS. 45 to 48, a dummy gate spacer 140P may be formed on a sidewall of the dummy gate electrode 120P.

While the dummy gate spacer 140P is formed, the dummy gate electrode 120P may be used as a mask to form first to fourth source/drain recesses 150R, 250R, 350R, and 450R between the dummy gate electrodes 120P.

The first source/drain recess 150R may be formed within the first mold fin type pattern FMS1. The second source/drain recess 250R may be formed within the second mold fin type pattern FMS2. The third source/drain recess 350R may be formed within the third mold fin type pattern FMS3. The fourth source/drain recess 450R may be formed within the fourth mold fin type pattern FMS4.

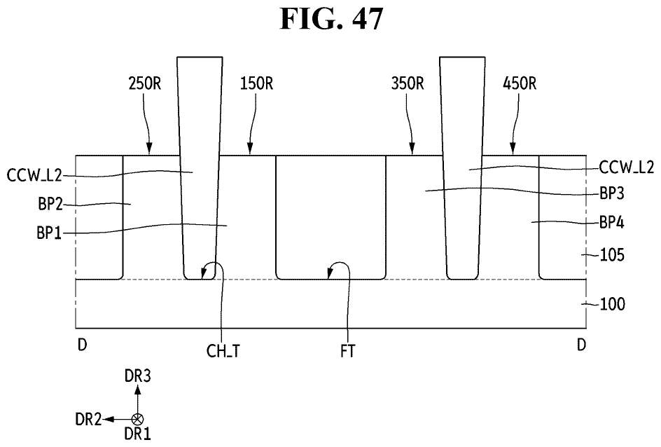

While the first to fourth source/drain recesses 150R, 250R, 350R, and 450R are formed, the second lower channel separation structure CCW_L2 may be formed. The second lower channel separation structure CCW_L2 may be formed by removing a portion of the first lower channel separation structure CCW_L1 exposed between the dummy gate electrodes 120P adjacent to each other. A portion of the first lower channel separation structure CCW_L1 that overlaps the dummy gate electrode 120P in the third direction DR3 may not be etched. For example, in the cross-sectional view such as FIG. 47, an upper surface of the second lower channel separation structure CCW_L2 is lower than the upper surface of the active pattern ACT_L disposed at the uppermost portion.

While the first to fourth source/drain recesses 150R, 250R, 350R, and 450R are formed, the fifth upper pattern structure UP5 may be removed. While the fifth upper pattern structure UP5 is removed, a portion of the pre-lower alignment insulating pattern 520P may be removed, so that the first lower alignment insulating pattern 520 may be formed.

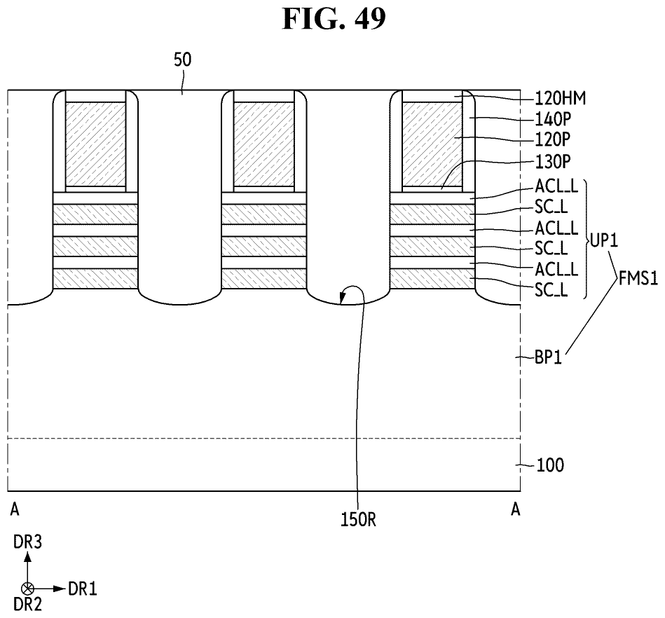

Referring to FIGS. 49 to 51, a sacrificial insulating film 50 may be formed on the first substrate 100.

The sacrificial insulating film 50 may fill the first to fourth source/drain recesses 150R, 250R, 350R, and 450R. The sacrificial insulating film 50 may fill a space positioned between the dummy gate electrodes 120P. The sacrificial insulating film 50 may fill a space between the first lower alignment insulating patterns 520 adjacent to each other in the fourth direction DR4. The sacrificial insulating film 50 may be formed up to an upper surface of the dummy gate capping film 120HM.

Next, an upper channel separation structure CCW_U is formed on the second lower channel separation structure CCW_L2. The upper channel separation structure CCW_U may be formed between the dummy gate electrodes 120P adjacent to each other in the first direction DR1. After the first to fourth source/drain recesses 150R, 250R, 350R, and 450R are formed, the upper channel separation structure CCW_U is formed.

The second portion CCW1_R22 of the second area of the first channel separation structure of FIG. 11 may be formed by the upper channel separation structure CCW_U

While the upper channel separation structure CCW_U is formed, a first upper alignment insulating pattern 525 may be formed on the plurality of first lower alignment insulating patterns 520. The first upper alignment insulating pattern 525 may be formed within an upper alignment pattern trench 525_T formed within the sacrificial insulating film 50. The upper alignment insulating pattern 525 may fill a portion of the upper alignment pattern trench 525_T. An upper surface of the upper alignment insulating pattern 525 may be lower than the upper surface of the sacrificial insulating film 50. A width of the upper alignment insulating pattern 525 in the fifth direction DR5 may be greater than a width of the upper channel separation structure CCW_U in the fifth direction DR5. As a result, the upper surface of the upper alignment insulating pattern 525 may be lower than the upper surface of the sacrificial insulating film 50.

As the first upper alignment insulating pattern 525 is formed on the plurality of first lower alignment insulating patterns 520 disposed below, the first upper alignment insulating pattern 525 may be firmly connected to the first lower alignment insulating patterns 520. Through this, even if the sacrificial insulating film 50 is removed later, a bonding state between the first upper alignment insulating pattern 525 and the first lower alignment insulating patterns 520 may be maintained.

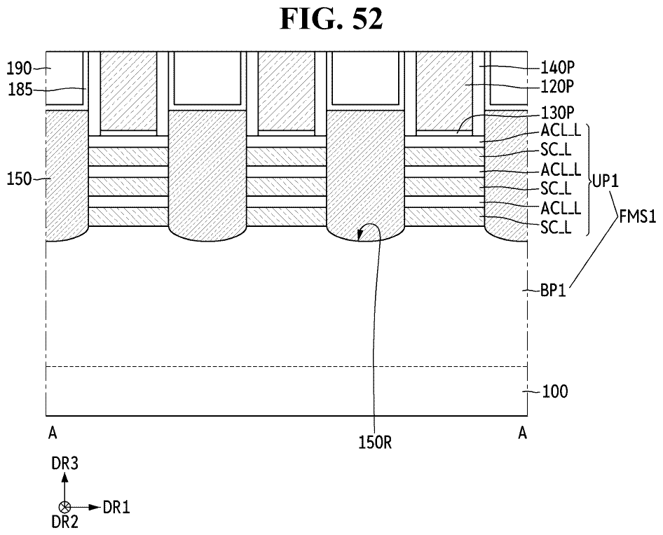

Referring to FIGS. 52 to 55, the sacrificial insulating film 50 is removed.

Through this, the first to fourth source/drain recesses 150R, 250R, 350R, and 450R may be exposed. In other words, the first to fourth upper pattern structures UP1, UP2, UP3, and UP4 may be exposed.

The first source/drain pattern 150 may be formed within the first source/drain recess 150R. The first source/drain pattern 150 may be formed on the first lower pattern BP1. The second source/drain pattern 250 may be formed within the second source/drain recess 250R. The second source/drain pattern 250 may be formed on the second lower pattern BP2. The third source/drain pattern 350 may be formed within the third source/drain recess 350R. The third source/drain pattern 350 may be formed on the third lower pattern BP3. The fourth source/drain pattern 450 may be formed within the fourth source/drain recess 450R. The fourth source/drain pattern 450 may be formed on the fourth lower pattern BP4.

The first to fourth source/drain patterns 150, 250, 350, and 450 may each be in contact with the upper channel separation structure CCW_U and the second lower channel separation structure CCW_L2.

While the first to fourth source/drain patterns 150, 250, 350, and 450 are formed, a mask pattern may be formed on the alignment mark area (20 in FIG. 1). That is, the source/drain pattern may not be formed in the alignment mark area (20 in FIG. 1).

After the first to fourth source/drain patterns 150, 250, 350, and 450 are formed, the mask pattern on the alignment mark area (20 in FIG. 1) may be removed.

Next, a source/drain etch stop film 185 and an upper interlayer insulating film 190 may be formed on the first to fourth source/drain patterns 150, 250, 350, and 450. While the source/drain etch stop film 185 and the upper interlayer insulating film 190 are formed, the dummy gate capping film 120HM may be removed. The dummy gate electrode 120P may be exposed.

The source/drain etch stop film 185 may be formed on the first lower alignment insulating pattern 520 and the first upper alignment insulating pattern 525.

Referring to FIGS. 52 to 54, 56, and 57, a gate trench 120t may be formed by removing the dummy gate electrode 120P and the dummy gate insulating film 130P.

The gate trench 120t may expose the first to fourth upper pattern structures UP1, UP2, UP3, and UP4. The gate trench 120t may extend in the second direction DR2.

Next, a first sheet pattern NS1 in contact with the second lower channel separation structure CCW_L2 and the first source/drain pattern 150 may be formed by removing the sacrificial pattern SC_L of the first upper pattern structure UP1 exposed by the gate trench 120t.

A second sheet pattern NS2 in contact with the second lower channel separation structure CCW_L2 and the second source/drain pattern 250 may be formed by removing the sacrificial pattern SC_L of the second upper pattern structure UP2 exposed by the gate trench 120t.

A third sheet pattern NS3 and a fourth sheet pattern NS4 may be formed by removing the sacrificial pattern SC_L of the third and fourth upper pattern structures UP3 and UP4 exposed by the gate trench 120t. The third sheet pattern NS3 and the fourth sheet pattern NS4 may be in contact with the second lower channel separation structure CCW2_L2.

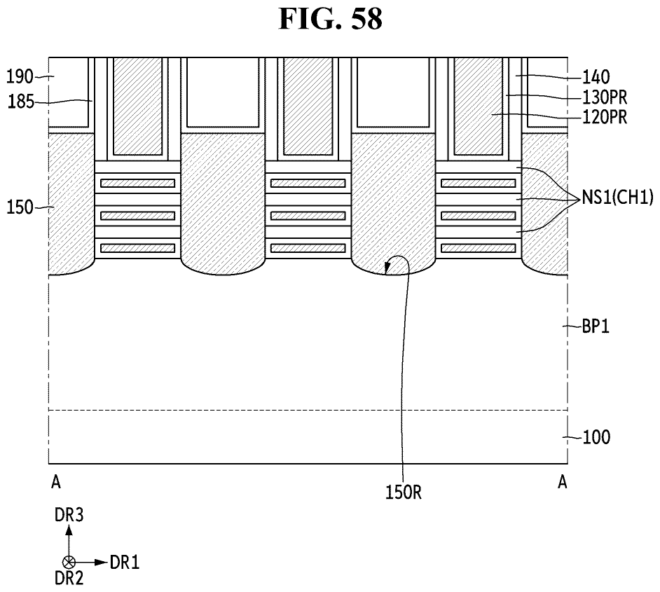

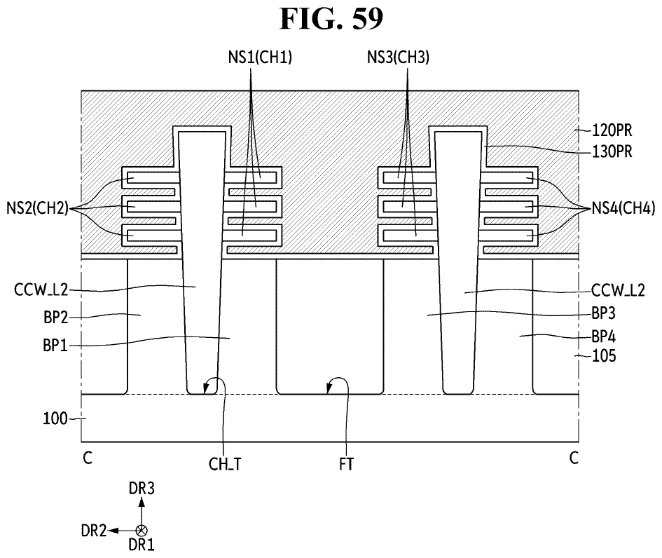

Referring to FIGS. 58 and 59, a pre-gate electrode 120PR and a pre-gate insulating film 130PR may be formed within the gate trench 120t.

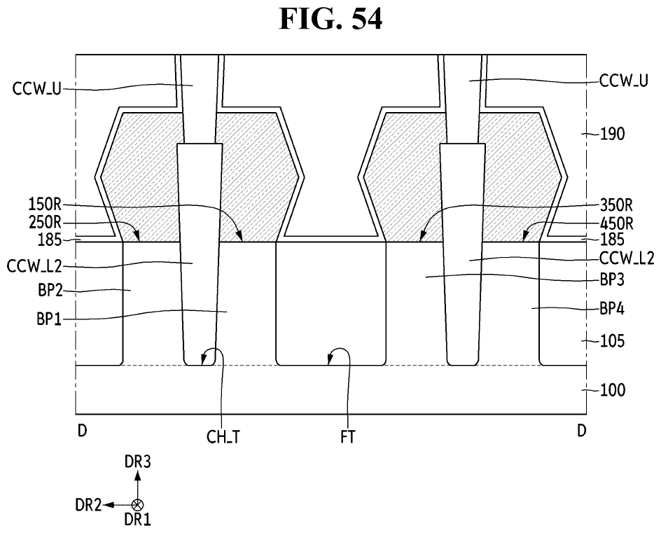

The pre-gate electrode 120PR may intersect the first to fourth sheet patterns NS1, NS2, NS3, and NS4. The pre-gate electrode 120PR may cover the upper surface of the second lower channel separation structure CCW_L2. Although not illustrated, an upper surface of the pre-gate electrode 120PR may be on the same plane as the upper surface of the upper channel separation structure (CCW_U in FIG. 54).

In FIGS. 4 to 7, the first to fourth gate structures GS1, GS2, GS3, and GS4 may be formed by removing portions of the pre-gate electrode 120PR and the pre-gate insulating film 130PR. The pre-gate electrode 120PR and the pre-gate insulating film 130PR may be etched until the upper surface of the second lower channel separation structure CCW_L2 is exposed. Through this, first to fourth gate structures GS1, GS2, GS3, and GS4) may be formed. First and second gate capping patterns 145 and 345 may be formed on the first to fourth gate structures GS1, GS2, GS3, and GS4.

In concluding the detailed description, those skilled in the art will appreciate that many variations and modifications may be made to the example embodiments without substantially departing from the principles of the present disclosure. Therefore, the disclosed example embodiments of the disclosure are used in a generic and descriptive sense only and not for purposes of limitation.

What is claimed is:

1. A semiconductor device comprising:
a base film;
a plurality of lower alignment insulating patterns disposed on the base film; and
an upper alignment insulating pattern disposed on the lower alignment insulating patterns, extending in a first direction, and in direct contact with each of the lower alignment insulating patterns,
wherein the lower alignment insulating patterns extend in a second direction perpendicular to the first direction and are spaced apart from each other in the first direction.

2. The semiconductor device of claim 1, wherein a width of each of the lower alignment insulating patterns in the second direction is greater than a width of the upper alignment insulating pattern in the second direction.

3. The semiconductor device of claim 1, further comprising:
a lower pattern disposed on the base film and including a plurality of sub-fin type patterns extending in the second direction,
wherein each of the lower alignment insulating patterns is disposed between the sub-fin type patterns adjacent to each other in the first direction and is in contact with the sub-fin type patterns.

4. The semiconductor device of claim 3, wherein a depth from a bottom surface of the upper alignment insulating pattern to the lowest portion of the lower alignment insulating pattern is equal to or greater than a depth from the bottom surface of the upper alignment insulating pattern to the lowest portion of the sub-fin type patterns.

5. The semiconductor device of claim 3, further comprising:
a field insulating film disposed on a sidewall of the lower pattern; and
an alignment pattern spacer disposed on an upper surface of the field insulating film and protruding in a third direction perpendicular to the first direction and the second direction.

6. The semiconductor device of claim 1, further comprising:
an alignment semiconductor pattern disposed on the base film and between the lower alignment insulating patterns adjacent to each other in the first direction.

7. The semiconductor device of claim 6,
wherein the alignment semiconductor pattern is spaced apart from the upper alignment insulating pattern in a third direction perpendicular to the first direction and the second direction, and
wherein the alignment semiconductor pattern is not in contact with the upper alignment insulating pattern.

8. The semiconductor device of claim 6, wherein a width of the alignment semiconductor pattern in the second direction is greater than a width of the upper alignment insulating pattern in the second direction.

9. A semiconductor device comprising:
a first lower pattern including a plurality of first sub-fin type patterns extending in a first direction;
a second lower pattern including a plurality of second sub-fin type patterns extending in a second direction perpendicular to the first direction;
a first alignment mark pattern including a plurality of first lower alignment insulating patterns disposed between the first sub-fin type patterns adjacent to each other in the second direction, and a first upper alignment insulating pattern disposed on the first lower alignment insulating patterns; and
a second alignment mark pattern including a plurality of second lower alignment insulating patterns disposed between the second sub-fin type patterns adjacent to each other in the first direction, and a second upper alignment insulating pattern disposed on the second lower alignment insulating patterns,
wherein the first upper alignment insulating pattern extends in the second direction and is in direct contact with each of the first lower alignment insulating patterns, and
wherein the second upper alignment insulating pattern extends in the first direction and is in direct contact with each of the second lower alignment insulating patterns.

10. The semiconductor device of claim 9, wherein a width of each of the first lower alignment insulating patterns in the first direction is greater than a width of the first upper alignment insulating pattern in the first direction.

11. The semiconductor device of claim 9, wherein a depth from a bottom surface of the first upper alignment insulating pattern to the lowest portion of the first lower alignment insulating patterns is equal to or greater than a depth from the bottom surface of the first upper alignment insulating pattern to the lowest portion of the first sub-fin type patterns.

12. The semiconductor device of claim 9, wherein a number of the first sub-fin type patterns included in the first lower pattern is greater than a number of the first lower alignment insulating patterns included in the first alignment mark pattern.

13. The semiconductor device of claim 9, further comprising:
a first alignment semiconductor pattern disposed on each of the first sub-fin type patterns and in contact with the first lower alignment insulating patterns; and
a second alignment semiconductor pattern disposed on each of the second sub-fin type patterns and in contact with the second lower alignment insulating patterns.

14. The semiconductor device of claim 13, wherein the first alignment semiconductor pattern includes the same material as the second alignment semiconductor pattern.

15. The semiconductor device of claim 13, wherein the first alignment semiconductor pattern is not in contact with a bottom surface of the first upper alignment insulating pattern.

16. The semiconductor device of claim 9, further comprising an alignment air gap disposed between the first sub-fin type patterns and the first upper alignment insulating pattern.

17. A semiconductor device comprising:
an active pattern disposed in a logic cell area, extending in a first direction, and including a first sidewall and a second sidewall opposite to each other in a second direction perpendicular to the first direction;
a channel separation structure extending in the first direction and in contact with the first sidewall of the active pattern;
a field insulating film in contact with the second sidewall of the active pattern;
a source/drain pattern disposed on the active pattern and in contact with the active pattern and the channel separation structure;
a gate structure disposed on the active pattern and in contact with the channel separation structure;
a first lower pattern disposed in an alignment mark area and including a plurality of sub-fin type patterns; and
an alignment mark pattern including a plurality of lower alignment insulating patterns disposed between adjacent sub-fin type patterns and an upper alignment insulating pattern disposed on the lower alignment insulating patterns,
wherein the upper alignment insulating pattern is in direct contact with each of the lower alignment insulating patterns.

18. The semiconductor device of claim 17,
wherein the active pattern includes a second lower pattern extending in the first direction, and a channel pattern spaced apart from the second lower pattern in a third direction perpendicular to the first direction and the second direction,
wherein the channel pattern includes a plurality of sheet patterns spaced apart from each other in the third direction,
wherein each sheet pattern of the plurality of sheet patterns is in contact with the channel separation structure, and
wherein the second lower pattern includes the first sidewall of the active pattern and the second sidewall of the active pattern.

19. The semiconductor device of claim 17,
wherein the lower alignment insulating patterns extend in the first direction,
wherein the upper alignment insulating pattern extends in the second direction, and
wherein a width of each of the lower alignment insulating patterns in the second direction is greater than a width of the upper alignment insulating pattern in the second direction.

20. The semiconductor device of claim 17, further comprising:
a sacrificial semiconductor pattern disposed within the first lower pattern; and
an alignment semiconductor pattern disposed on each of the sub-fin type patterns and in contact with the lower alignment insulating patterns,
wherein the sacrificial semiconductor pattern is disposed below the source/drain pattern, and
wherein the sacrificial semiconductor pattern includes the same material as the alignment semiconductor pattern.
